(19) United States
(12) Patent Application Publication
(10) Pub. No.: US 2018/0096719 A1
(43) Pub. Date: Apr. 5, 2018

(54) STAGGERING INITIATION OF REFRESH IN A GROUP OF MEMORY DEVICES

(71) Applicant: Intel Corporation, Santa Clara, CA (US)

(72) Inventors: Shigeki TOMISHIMA, Portland, OR (US); John B. HALBERT, Beaverton, OR (US); Kuljit S. BAINS, Olympia, WA (US)

(21) Appl. No.: 15/282,766

(22) Filed: Sep. 30, 2016

(51) Int. Cl. G11C 11/406; G11C 11/4076; G11C 11/4091; G11C 7/10

(52) U.S. Cl. CPC G11C 11/40615; G11C 7/1072; G11C 11/4091; G11C 11/4076

(57) ABSTRACT

Memory refresh includes timing offsets for different memory devices, to initiate refresh of different memory devices at different times. A memory controller sends a refresh command to cause refresh of multiple memory devices. In response to the refresh command, the multiple memory devices initiate refresh with timing offsets relative to another of the memory devices. The timing offsets reduce the instantaneous power surge associated with all memory devices starting refresh simultaneously.

### FIELD

The descriptions are generally related to memory subsystems, and more particular descriptions are related to the timing of refresh operations of memory devices.

### COPYRIGHT NOTICE/PERMISSION

Portions of the disclosure of this patent document may contain material that is subject to copyright protection. The copyright owner has no objection to the reproduction by anyone of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright © 2016, Intel Corporation, All Rights Reserved.

### BACKGROUND

Most electronic device utilize commodity volatile memory devices for operational storage. A volatile memory device is one that needs to be refreshed to maintain data in a deterministic state. Interruption of power to a volatile memory device results in indeterminacy of the data stored in the memory. The most common volatile memory devices are dynamic random access memory (DRAM) devices, which can refer to a wide variety of commodity devices of different capacity, bus width, and performance. While size of storage cells, or the memory cell in a memory devices, for commodity DRAM devices continues to shrink, the increase in processor or central processing unit (CPU) performance continues to increase. Thus, there are increased demands for data bandwidth (BW) and capacity in memory devices.

DRAM cell refresh time tends to follow DRAM cell size, and thus, as semiconductor processing technologies generate smaller DRAM cell size, the time between refreshes shrinks. Typical volatile memory includes a capacitor that needs to be charged to hold the value of the memory cell. The time between refreshes shrinks because of increasing difficulty in maintaining the same cell capacitance with smaller cells. Additionally, the capacitor discharge tends to increase with smaller cell size due to larger cell leakage caused by smaller cell dimensions (such as the 2 dimensional footprint). For example, the time tREF is a refresh time, and indicates a time window after which a memory cell should be refreshed to prevent data corruption, and is based on an amount of time the cell can retain data in a valid state. Data retention time for volatile DRAMs was traditionally specified to be 64 ms (milliseconds), which in emerging devices has now been cut in half to 32 ms. All rows are refreshed within the tREF window. With a memory architecture of 8K (8192) rows, the system would need to issue a refresh command every 7.8us (microseconds) to maintain determinism of the memory contents ( 64 ms/8K=7.81us). The refresh commands needed to refresh the data to maintain its determinism has likewise been cut from an average of one refresh command every 7.8us to 3.9us on those emerging devices (referred to as tREFI, or refresh interval time). The tREFI refers to the average time between issuance of refresh commands to refresh all rows within the refresh window. The shorter refresh periods would tend to suspend and block normal Read and Write operations more frequently.

Not only is bandwidth affected by the increased bandwidth consumption for refresh commands, but the increased capacities further complicate the refresh issues. Larger capacities have been achieved through larger DRAM die size, with increasing numbers of rows of memory devices, or wordlines (WLs). For example, changing from 4 Gb (gigabit) dies using semiconductor processing technologies with 30 nm (nanometer) process nodes to 8 Gb dies on 20 nm process nodes enabled the doubling of the number of wordlines. It will be understood that the number of rows depends on the array architecture such as row and column address mapping and page size. Thus, the space saving can double the number of rows or otherwise increase the memory density. The increase of memory dies to 12 Gb, 16 Gb, or other capacities will result in further increase in the number of WLs. More WLs per die means more WLs that need to be refreshed within the same refresh window (e.g., 32 ms). Refreshing more WLs in the same refresh window is accomplished by a decrease in the time between refreshes (tREFI), or to increase the number of rows refreshed per refresh command (e.g., multiple internal refresh operations in response to a single external refresh command).

Thus, refreshing is necessary in volatile memory devices, but consumes power and memory subsystem bandwidth. Refreshing more rows at a time increases the instantaneous current draw of the memory subsystem, which increases peak power consumption. Memory systems that include multiple memory dies refreshed in parallel amplifies the increase of peak power consumption, and further affects performance as the devices are unavailable at the same time.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of an embodiment of a memory subsystem in which refresh staggering can be performed.

FIG. 2 is a block diagram of an embodiment of a system with refresh staggering by configuration setting.

FIG. 3 is a block diagram of an embodiment of an eight stack device that staggers refresh by memory device configuration.

FIG. 4 is a block diagram of an embodiment of a system with refresh staggering by architecture design.

FIG. 5 is a block diagram of an embodiment of an eight stack device that staggers refresh by device architecture.

FIG. 6 is a block diagram of an embodiment of an eight stack device that staggers refresh by both device architecture and memory device configuration.

FIG. 7A is a timing diagram of an embodiment of refresh staggering where different ranks initiate refresh offset from each other.

FIG. 7B is a timing diagram of another embodiment of refresh staggering where different ranks initiate refresh offset from each other.

FIG. 8 is a timing diagram of an embodiment of refresh staggering where different ranks initiate refresh offset from each other, and internally the ranks stagger row refresh.

FIGS. 9A-9B are representations of an embodiment of a signal connection for a device architecture to enable staggering refresh in a stack of memory devices.

FIG. 10A is a flow diagram of an embodiment of a process for staggering memory device refresh.

FIG. 10B is a flow diagram of an embodiment of a process for staggering refresh start by configuration settings.

FIG. 10C is a flow diagram of an embodiment of a process for staggering refresh start by a cascade refresh signal.

FIG. 11 is a block diagram of an embodiment of a computing system in which refresh staggering can be implemented.

FIG. 12 is a block diagram of an embodiment of a mobile device in which refresh staggering can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, the initiation of refresh is staggered among different memory devices of a group. The initiation of refresh operations includes timing offsets for different memory devices, to stagger the start of refresh for different memory devices to different times. A memory controller sends a refresh command to cause refresh of multiple memory devices, and in response to the refresh command, the multiple memory devices initiate refresh with timing offsets relative to another of the memory devices. The timing offsets reduce the instantaneous power surge associated with all memory devices starting refresh simultaneously. The timing offsets also reduces concurrent unavailability of memory devices due to refresh.

Thus, with refresh staggering, a system can maintain refresh operation without degradation of data, while reducing peak power consumption, and improving memory device availability. In one embodiment, the system staggers memory device refresh by providing a configuration for the memory devices, where different devices have different configurations. The different configurations can provide delay parameters for the memory devices to cause them to begin refresh operations at different times in response to a refresh command. More details are provided below. In one embodiment, the system staggers memory device refresh by architecture of the system, and specifically building a delay into the logic and routing of the refresh control signals. More details are provided below. In one embodiment, the system staggers memory device refresh by both architecture and device configuration.

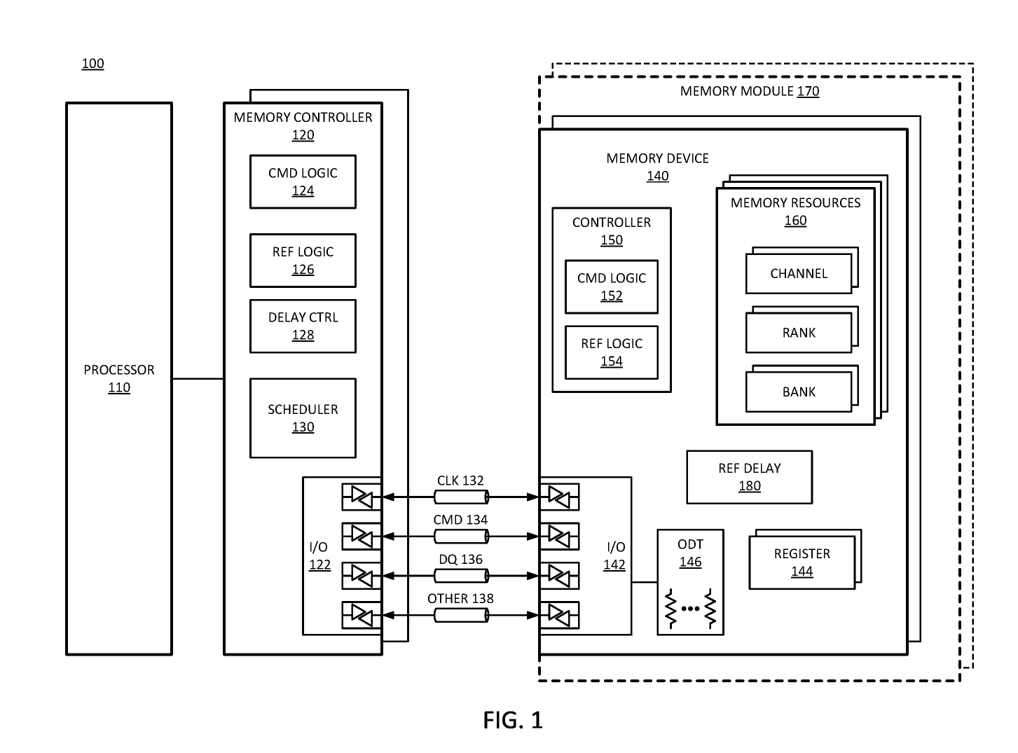

FIG. 1 is a block diagram of an embodiment of a memory subsystem in which refresh staggering can be performed. System 100 includes a processor and elements of a memory subsystem in a computing device. Processor 110 represents a processing unit of a computing platform that may execute an operating system (OS) and applications, which can collectively be referred to as the host or the user of the memory. The OS and applications execute operations that result in memory accesses. Processor 110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 100 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (double data rate version 3, original release by JEDEC (Joint Electronic Device Engineering Council) on Jun. 27, 2007, currently on release 21), DDR4 (DDR version 4, initial specification published in September 2012 by JEDEC), DDR4E (DDR version 4, extended, currently in discussion by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (currently in discussion by JEDEC), HBM2 (HBM version 2), currently in discussion by JEDEC), or others or combinations of memory technologies, and technologies based on derivatives or extensions of such specifications.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, other byte addressable nonvolatile memory devices, or memory devices that use chalcogenide phase change material (e.g., chalcogenide glass). In one embodiment, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 120 represents one or more memory controller circuits or devices for system 100. Memory controller 120 represents control logic that generates memory access commands in response to the execution of operations by processor 110. Memory controller 120 accesses one or more memory devices 140. Memory devices 140 can be DRAM devices in accordance with any referred to above. In one embodiment, memory devices 140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. As used herein, coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 120 manages a separate memory channel, although system 100 can be configured to have multiple channels managed by a single controller, or to have multiple controllers on a single channel. In one embodiment, memory controller 120 is part of host processor 110, such as logic implemented on the same die or implemented in the same package space as the processor.

Memory controller 120 includes I/O interface logic 122 to couple to a memory bus, such as a memory channel as referred to above. I/O interface logic 122 (as well as I/O interface logic 142 of memory device 140) can include pins, pads, connectors, signal lines, traces, or wires, or other hardware to connect the devices, or a combination of these. I/O interface logic 122 can include a hardware interface. As illustrated, I/O interface logic 122 includes at least drivers/transceivers for signal lines. Commonly, wires within an integrated circuit interface couple with a pad, pin, or connector to interface signal lines or traces or other wires between devices. I/O interface logic 122 can include drivers, receivers, transceivers, or termination, or other circuitry or combinations of circuitry to exchange signals on the signal lines between the devices. The exchange of signals includes at least one of transmit or receive. While shown as coupling I/O 122 from memory controller 120 to I/O 142 of memory device 140, it will be understood that in an implementation of system 100 where groups of memory devices 140 are accessed in parallel, multiple memory devices can include I/O interfaces to the same interface of memory controller 120. In an implementation of system 100 including one or more memory modules 170, I/O 142 can include interface hardware of the memory module in addition to interface hardware on the memory device itself. Other memory controllers 120 will include separate interfaces to other memory devices 140.

The bus between memory controller 120 and memory devices 140 can be implemented as multiple signal lines coupling memory controller 120 to memory devices 140. The bus may typically include at least clock (CLK) 132, command/address (CMD) 134, and write data (DQ) and read DQ 136, and zero or more other signal lines 138. In one embodiment, a bus or connection between memory controller 120 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 120 and memory devices 140. An example of a serial bus technology is 86106 encoding and transmission of high-speed data with embedded clock over a single differential pair of signals in each direction.

It will be understood that in the example of system 100, the bus between memory controller 120 and memory devices 140 includes a subsidiary command bus CMD 134 and a subsidiary bus to carry the write and read data, DQ 136. In one embodiment, the data bus can include bidirectional lines for read data and for write/command data. In another embodiment, the subsidiary bus DQ 136 can include unidirectional write signal lines for write and data from the host to memory, and can include unidirectional lines for read data from the memory to the host. In accordance with the chosen memory technology and system design, other signals 138 may accompany a bus or sub bus, such as strobe lines DQS. Based on design of system 100, or implementation if a design supports multiple implementations, the data bus can have more or less bandwidth per memory device 140. For example, the data bus can support memory devices that have either a x32 interface, a x16 interface, a x8 interface, or other interface. The convention “xW,” where W is an integer that refers to an interface size or width of the interface of memory device 140, which represents a number of signal lines to exchange data with memory controller 120. The interface size of the memory devices is a controlling factor on how many memory devices can be used concurrently per channel in system 100 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

Memory devices 140 represent memory resources for system 100. In one embodiment, each memory device 140 is a separate memory die. In one embodiment, each memory device 140 can interface with multiple (e.g., 2) channels per device or die. Each memory device 140 includes I/O interface logic 142, which has a bandwidth determined by the implementation of the device (e.g., x16 or x8 or some other interface bandwidth). I/O interface logic 142 enables the memory devices to interface with memory controller 120. I/O interface logic 142 can include a hardware interface, and can be in accordance with I/O 122 of memory controller, but at the memory device end. In one embodiment, multiple memory devices 140 are connected in parallel to the same command and data buses. In another embodiment, multiple memory devices 140 are connected in parallel to the same command bus, and are connected to different data buses. For example, system 100 can be configured with multiple memory devices 140 coupled in parallel, with each memory device responding to a command, and accessing memory resources 160 internal to each. For a Write operation, an individual memory device 140 can write a portion of the overall data word, and for a Read operation, an individual memory device 140 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one embodiment, memory devices 140 are disposed directly on a motherboard or host system platform (e.g., a PCB (printed circuit board) on which processor 110 is disposed) of a computing device. In one embodiment, memory devices 140 can be organized into memory modules 170. In one embodiment, memory modules 170 represent dual inline memory modules (DIMMs). In one embodiment, memory modules 170 represent other organization of multiple memory devices to share at least a portion of access or control circuitry, which can be a separate circuit, a separate device, or a separate board from the host system platform. Memory modules 170 can include multiple memory devices 140, and the memory modules can include support for multiple separate channels to the included memory devices disposed on them. In another embodiment, memory devices 140 may be incorporated into the same package as memory controller 120, such as by techniques such as multi-chip-module (MCM), package-on-package, through-silicon VIA (TSV), or other techniques or combinations. Similarly, in one embodiment, multiple memory devices 140 may be incorporated into memory modules 170, which themselves may be incorporated into the same package as memory controller 120. It will be appreciated that for these and other embodiments, memory controller 120 may be part of host processor 110.

Memory devices 140 each include memory resources 160. Memory resources 160 represent individual arrays of memory locations or storage locations for data. Typically memory resources 160 are managed as rows of data, accessed via wordline (rows) and bitline (individual bits within a row) control. Memory resources 160 can be organized as separate channels, ranks, and banks of memory. Channels may refer to independent control paths to storage locations within memory devices 140. Ranks may refer to common locations across multiple memory devices (e.g., same row addresses within different devices). Banks may refer to arrays of memory locations within a memory device 140. In one embodiment, banks of memory are divided into sub-banks with at least a portion of shared circuitry (e.g., drivers, signal lines, control logic) for the sub-banks. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 140 include one or more registers 144. Register 144 represents one or more storage devices or storage locations that provide configuration or settings for the operation of the memory device. In one embodiment, register 144 can provide a storage location for memory device 140 to store data for access by memory controller 120 as part of a control or management operation. In one embodiment, register 144 includes one or more Mode Registers. In one embodiment, register 144 includes one or more multipurpose registers. The configuration of locations within register 144 can configure memory device 140 to operate in different “mode,” where command information can trigger different operations within memory device 140 based on the mode. Additionally or in the alternative, different modes can also trigger different operation from address information or other signal lines depending on the mode. Settings of register 144 can indicate configuration for I/O settings (e.g., timing, termination or ODT (on-die termination) 146, driver configuration, or other I/O settings).

In one embodiment, memory device 140 includes ODT 146 as part of the interface hardware associated with I/O 142. ODT 146 can be configured as mentioned above, and provide settings for impedance to be applied to the interface to specified signal lines. In one embodiment, ODT 146 is applied to DQ signal lines. In one embodiment, ODT 146 is applied to command signal lines. In one embodiment, ODT 146 is applied to address signal lines. In one embodiment, ODT 146 can be applied to any combination of the preceding. The ODT settings can be changed based on whether a memory device is a selected target of an access operation or a non-target device. ODT 146 settings can affect the timing and reflections of signaling on the terminated lines. Careful control over ODT 146 can enable higher-speed operation with improved matching of applied impedance and loading. ODT 146 can be applied to specific signal lines of I/O interface 142, 122, and is not necessarily applied to all signal lines.

Memory device 140 includes controller 150, which represents control logic within the memory device to control internal operations within the memory device. For example, controller 150 decodes commands sent by memory controller 120 and generates internal operations to execute or satisfy the commands. Controller 150 can be referred to as an internal controller, and is separate from memory controller 120 of the host. Controller 150 can determine what mode is selected based on register 144, and configure the internal execution of operations for access to memory resources 160 or other operations based on the selected mode. Controller 150 generates control signals to control the routing of bits within memory device 140 to provide a proper interface for the selected mode and direct a command to the proper memory locations or addresses.

Referring again to memory controller 120, memory controller 120 includes scheduler 130, which represents logic or circuitry to generate and order transactions to send to memory device 140. From one perspective, the primary function of memory controller 120 could be said to schedule memory access and other transactions to memory device 140. Such scheduling can include generating the transactions themselves to implement the requests for data by processor 110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 120 typically includes logic to allow selection and ordering of transactions to improve performance of system 100. Thus, memory controller 120 can select which of the outstanding transactions should be sent to memory device 140 in which order, which is typically achieved with logic much more complex that a simple first-in first-out algorithm. Memory controller 120 manages the transmission of the transactions to memory device 140, and manages the timing associated with the transaction. In one embodiment, transactions have deterministic timing, which can be managed by memory controller 120 and used in determining how to schedule the transactions.

Referring again to memory controller 120, memory controller 120 includes command (CMD) logic 124, which represents logic or circuitry to generate commands to send to memory devices 140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 140, memory controller 120 can issue commands via I/O 122 to cause memory device 140 to execute the commands. In one embodiment, controller 150 of memory device 140 receives and decodes command and address information received via I/O 142 from memory controller 120. Based on the received command and address information, controller 150 can control the timing of operations of the logic and circuitry within memory device 140 to execute the commands. Controller 150 is responsible for compliance with standards or specifications within memory device 140, such as timing and signaling requirements. Memory controller 120 can implement compliance with standards or specifications by access scheduling and control.

In one embodiment, memory controller 120 includes refresh (REF) logic 126. Refresh logic 126 can be used for memory resources that are volatile and need to be refreshed to retain a deterministic state. In one embodiment, refresh logic 126 indicates a location for refresh, and a type of refresh to perform. Refresh logic 126 can trigger self-refresh within memory device 140, or execute external refreshes which can be referred to as auto refresh commands) by sending refresh commands, or a combination. In one embodiment, system 100 supports all bank refreshes as well as per bank refreshes. All bank refreshes cause the refreshing of banks within all memory devices 140 coupled in parallel. Per bank refreshes cause the refreshing of a specified bank within a specified memory device 140. In one embodiment, controller 150 within memory device 140 includes refresh logic 154 to apply refresh within memory device 140. In one embodiment, refresh logic 154 generates internal operations to perform refresh in accordance with an external refresh received from memory controller 120. Refresh logic 154 can determine if a refresh is directed to memory device 140, and what memory resources 160 to refresh in response to the command.

In one embodiment, system 100 includes multiple memory devices 140 in a group, and staggers refresh initiation among the memory devices. The group can refer to a rank, or to multiple devices within a multi-device package, or other group where advantage could be gained by staggering the refreshes. In one embodiment, memory device 140 represents a single memory die, which is packaged together with other memory dies in a common package, such as a stack of memory dies. In one embodiment, memory device 140 represents a single memory chip, and the group includes other memory chips that will be refreshed in parallel with memory device 140. In one embodiment, memory device 140 represents a multi-device package that includes multiple memory dies, each of which can include its own controller and other logic.

In an embodiment of system 100 that implements staggered refresh, memory controller 120 includes delay control 128. Delay control 128 is an abstraction to represent one or more mechanisms of memory controller 120 to manage staggered refresh delay. Delay control 128 can include logic that is part of refresh logic 126, command logic 124, or scheduler 130, or a combination. In one embodiment, delay control 128 includes logic to generate MRS (mode register set) commands to set a delay parameter for memory devices 140. Memory controller 120 can compute a delay based on the system configuration and the memory device type. Memory controller 120 can include a fixed delay and configure memory devices 140 in accordance with the fixed delay.

In one embodiment, delay control 128 includes logic to determine a delay that exists among memory devices 140 that occurs as a result of architectural design of the system (as described in more detail below). Memory controller 120 can determine the delay during an initialization of the memory system and training with the memory devices. Whether memory controller 120 creates refresh delays or simply discovers them, scheduler 130 can adjust its operation in accordance with the delays in refreshing among the memory devices. A staggered refresh start can enable different combinations of devices to be available for access, even after a refresh command is sent. Thus, scheduler 130 can account for the delays in scheduling access transactions.

Memory device 140 is illustrated to include refresh delay 180, which represents the delay mechanism for memory device 140 relative to start of refresh by other memory devices in a group. As mentioned above, in one embodiment, refresh delay 180 results from an architectural design. For example, the memory devices of the group can be coupled in a cascade, which ensures that the refresh command will first reach one device and trigger the start of refresh in that device prior to reaching another device to trigger refresh in the other device. In one embodiment, refresh delay 180 results from one or more configuration settings of memory device 140, such as a setting stored in register 144. In such an embodiment, when refresh logic 154 receives an external refresh or auto refresh command, it can read the setting from register 144, and wait for a period refresh delay 180 prior to controller 150 generating the internal commands to cause the internal refresh operations. In either the case of architecture or configuration, memory device 140 initiates refresh at a timing offset relative to another memory device. In one embodiment, controller 150 can wait a period refresh delay 180 prior to generating internal commands to cause internal refresh operations in response to a self-refresh command received from memory controller 120. Thus, in one embodiment, memory devices 140 can stagger refresh start in response to an external or auto refresh command. In one embodiment, memory devices 140 can stagger refresh start in response to a self-refresh command.

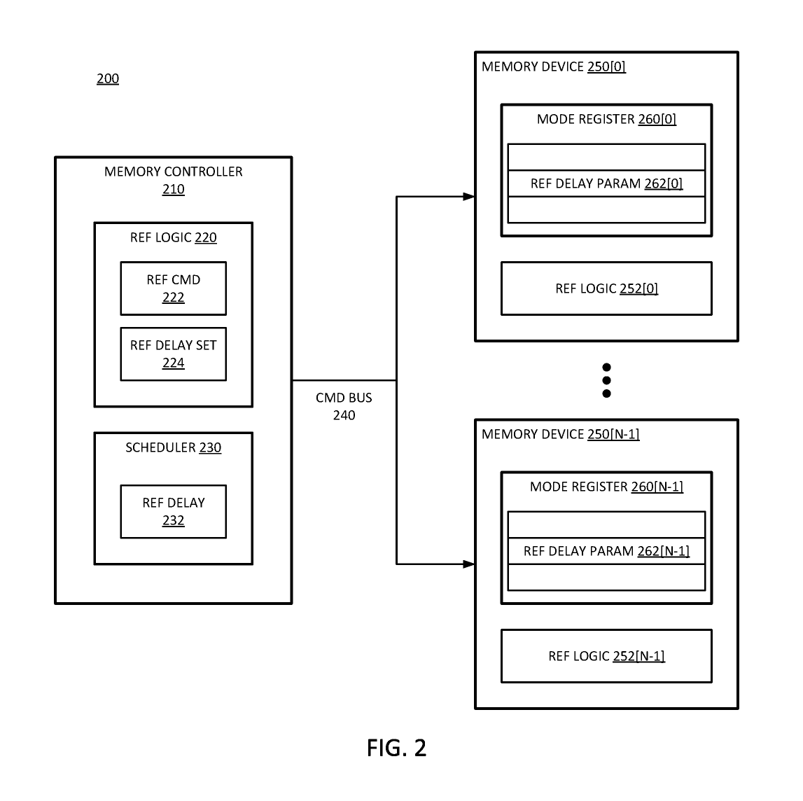

FIG. 2 is a block diagram of an embodiment of a system with refresh staggering by configuration setting. System 200 illustrates elements of a memory system, and is one example of an embodiment of system 100 of FIG. 1. System 200 includes memory controller 210 to manage access to, and refresh of, volatile memory devices 250. It will be understood that reference to memory devices 250 is a shorthand referring collectively to the N memory devices 250[0] to 250[N-1] represented in system 200, where N is an integer greater than 1. The N memory devices 250[0] to 250[N-1] respectively include corresponding mode registers 260[0] to 260[N-1] with refresh delay parameters (ref delay param) 262[0] to 262[N-1], and refresh logic 252[0] to 252[N-1], and can all likewise be referred to by the same shorthand explained above. Memory devices 250 are part of a group of memory devices that will be refreshed in response to the same refresh command from memory controller 210.

In one embodiment, memory controller 210 includes refresh logic 220 with refresh command (ref cmd) logic 222 and refresh delay set logic 224. Refresh command logic 222 represents logic to generate refresh commands to send to memory devices 250. In one embodiment, refresh command logic 222 generates all bank refresh commands. In one embodiment, refresh command logic 222 generates per bank refresh commands. In one embodiment, refresh command logic 222 generates all bank and per bank refresh commands.

Memory controller 210 includes controller 230 to schedule commands to send to memory devices 250. Part of scheduling commands to send to the memory devices includes the determination of when to send commands based on when memory devices 250 will be in refresh or executing a refresh operation. In one embodiment, the refresh timing includes the start time of each individual memory device 250, where the memory devices have different refresh delays to start refresh at different times. Thus, scheduler 230 is illustrated to include refresh delay 232, which represents the logic within memory controller 210 to factor the refresh timing offsets of different delays. Based on different delays or offsets, memory device 250[N-1] may not be in refresh at the same time as memory device 250[0]. For example, consider a configuration where memory device 250[0] initiates refresh immediately in response to receipt of a refresh command received from memory controller 210 over command (cmd) bus 240, while memory device 250[N-1] is configured to wait a period of time before initiating refresh.

In one embodiment, mode registers 260 of memory devices 250 include a refresh delay parameter 262, which indicates a delay to be applied in response to receipt of a refresh command. In one embodiment, memory controller 210 includes refresh delay set 224 to determine different delays for different memory devices, and causes the memory controller to send a configuration command (e.g., a mode register set (MRS) command) to set refresh delay parameters 262. For example, memory controller 210 can configure the refresh delay parameters during initialization of system 200. Differences in the delay parameters can change when memory devices 250 initiate refresh. Even if all memory devices 250 receive a refresh command on command bus 240 at approximately or substantially the same time, one could delay a first amount of time, and another could delay a second amount of time different from the first amount of time. Refresh delay parameters 262 can thus shift refresh operations in time.

In one embodiment, memory controller 210 sets refresh delay parameters 262, and thus knows the specific refresh timing for each memory device 250. Memory controller 210 uses such information as refresh delay information 232, which is considered by scheduler 230 in scheduling access transactions to memory devices 250. In one embodiment, memory controller 210 can read a configuration from mode registers 260, which was not set by the memory controller. However, by reading refresh delay parameters 262 for memory devices 250, memory controller 210 will know of the specific refresh timing for each memory device 250, and can consider such information in transaction scheduling.

It will be understood that refresh logic 220 of memory controller 210 can issue a self-refresh command, which is a command to trigger one or more memory devices 250 to enter a low power state and internally manage refresh operations to maintain valid data. Self-refresh is managed internally by the memory devices, as opposed to external refresh commands managed by memory controller 210. Memory devices 250 perform self-refresh operations based on an internal timing or clock signal, and control the timing and generation of internal refresh commands. External refresh or auto refresh refers to a refresh command from memory controller 210 that triggers memory devices 250 to perform refresh in active operation as opposed to a low power state, and based on a timing or clock signal from memory controller 210, as opposed to an internal clock. Thus, memory devices 250 remain synchronized to the timing of memory controller 210 during external refresh operations. In response to an external refresh command, memory devices 250 generate internal refresh operations in response to the command, and synchronized to external timing. As described herein, the timing control of the internal refresh operations in response to an external refresh command can include the introduction of a delay or timing offset in the initiation of the internal refresh operations. Thus, at least one of memory devices 250 will initiate refresh at an offset relative to at least one other of memory devices 250. In one embodiment, the timing control of the internal refresh operations in response to a self-refresh command can also include the introduction of a delay or timing offset, which can prevent the devices from initiating self-refresh at the same time.

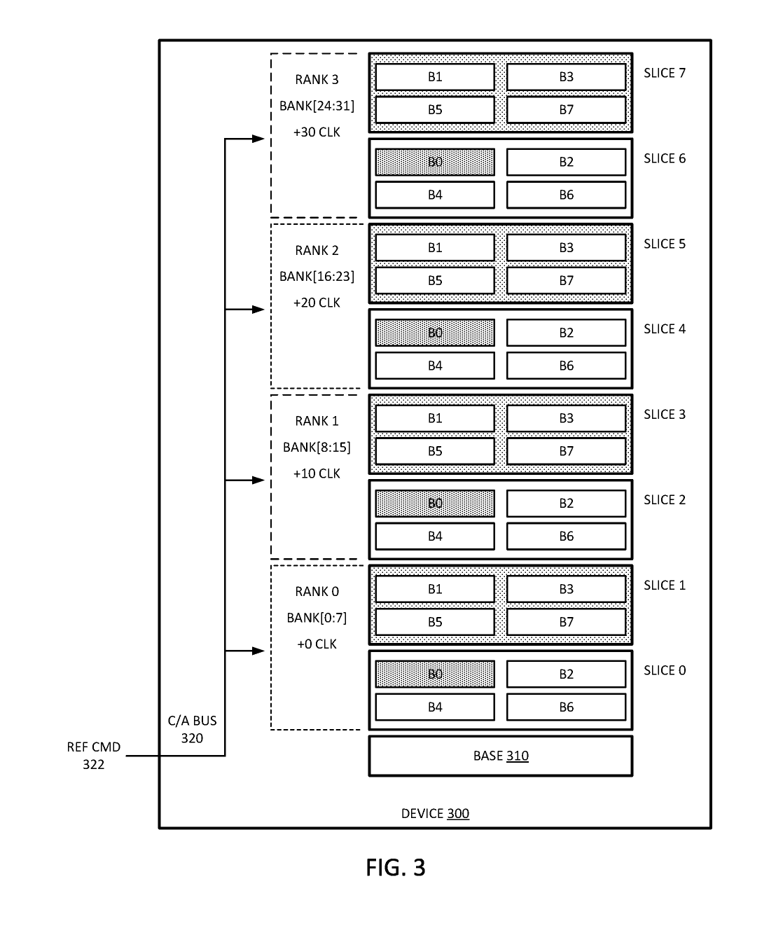

FIG. 3 is a block diagram of an embodiment of an eight stack device that staggers refresh by memory device configuration. Device 300 provides one example of an embodiment of a multichip package including multiple memory devices. Device 300 can be one example of an implementation of memory devices 250 of system 200. The more specific implementation of device 300 includes an eight-high stack of DRAM devices. Device 300 can be one example of an HBM memory device.

Device 300 includes a semiconductor package that can be mounted to a board or to another substrate. Device 300 includes base 310, which represents a common substrate for the stack of DRAM devices. Typically, base 310 includes interconnections to the externally-facing I/O for device 300. For example, device 300 can include pins or connectors, and traces or other wires or electrical connections to those pins/connectors. The multiple DRAM devices are stacked on base 310, one on top of each other. In device 300 the individual DRAM devices are identified by a designation of “Slices.” Thus, Slices[0:7] represent the eight DRAM devices stacked on base 310. The connections from the package of device 300 reach the individual Slices by means of TSVs (through silicon vias), or other connections, or a combination. A TSV refers to a trace that extends through the entire body of the device. Typically, the DRAM die is thinned to a desired thickness to enable putting TSVs through the device. The TSV can connect the electronics of die to a connector that enables the die to be mounted in a stack. The electronics of the die refers to traces, switches, memory, logic, and other components processed into the die.

For purposes of illustration, device 300 can be considered to have eight Slices organized as four ranks, Ranks[0:3]. Each Rank includes two adjacent Slices, where each Slice is illustrated to have four banks. The four banks are organized across the two Slices as Banks[0:7]; for example, SliceO includes four Banks identified as B0, B2, B4, and B6, and Slice1 includes four Banks identified as B1, B3, B5, and B7. Thus, SliceO includes the even-numbered banks, and Slice1 includes the odd-numbered banks. These bank number will be understood to refer to the eight banks within the Rank. The system-level bank number can be understood as the numbers shown, with an offset of 0, 8, 15, or 24. For example, Slice2 also includes four Banks identified as B0, B2, B4, and B6, and Slice3 includes four Banks identified as B1, B3, B5, and B7. These Banks are Banks[0:7] for Rank1, and are Banks[8:15] for the system. It will be understood that the organization shown and described is not limiting, and is solely for purposes of illustration. Other configurations are possible, with different numbers of Slices, with different numbers of Banks, different numbers of Ranks, different numbers of DRAM devices per Rank, different organization of the Bank designations, or a combination.

As illustrated, Rank0 includes Slices[0:1] with Banks[0:7], Rank1 includes Slices[2:3] with Banks[8:15], Rank2 includes Slices[4:5] with Banks[16:23], and Rank3 includes Slices[6:7] with Banks[24:31]. In one embodiment, Slices[0:7] share command/address (C/A) bus 320, in a multidrop bus configuration, where all devices are coupled to the same signal lines. In such an embodiment, refresh command (ref cmd) 322 received on C/A bus 320 from an associated memory controller (not specifically illustrated) reaches all Slices substantially at the same time, with time differences being only the propagation delay on the signal lines (e.g., TSVs) to the devices further out on the C/A bus.

It will be understood that the representation of C/A bus 320 is illustrated to show that the command and address bus couples to the various Ranks of DRAM devices, which would then all receive refresh command 322 at substantially the same time. A practical implementation of C/A bus 320 would come into device 300 to base 310, and be propagated to Slices[0:7] via stacked connections.

Thus, device 300 illustrates a single refresh trigger for all DRAM devices, which then implement the refresh at different timings. For example, Rank0 with Slices[0:1] includes an offset of +0 CLK, or zero clock cycles. Thus, the two DRAM devices of Rank0 can implement internal operations to execute the refresh as soon as refresh command 322 is received. Rank1 with Slices[2:3] includes an offset of +10 CLK, or delaying 10 clock cycles after capturing refresh command 322 before beginning internal refresh operations. Thus, the two DRAM devices of Rank1 delay for 10 clock cycles relative to the DRAM devices of Rank0. Furthermore, Rank2 includes an offset of +20 CLK, and Rank3 includes an offset of +30 CLK. It will be understood that other offsets can be used. The memory controller can set the delay via configuration setting commands, or the DRAM devices can include a configuration based on the configuration of the device (e.g., a hard coded configuration).

Thus, in one embodiment, after capturing refresh command 322, each DRAM die or DRAM device (e.g., Slice) can delay starting internal refresh operations in accordance with a configuration setting. Such delays can provide a cascade of refresh start times, for example, to have the Slices start at a delay of 0 clocks, N clocks, 2N clocks, and so forth, where N is a number of clock cycles. While N=10 is illustrated in FIG. 3, other numbers could be used instead, either smaller or larger. In one embodiment, the delay is configurable based on multiple possible delays, which can enable setting longer or slower delays for each system implementation. It will be understood that instead of a number of clock cycles, the delay could be specified as an amount of time or an absolute delay time (e.g., delay by 10 ns). However, delaying by clock cycles is much simpler than delay by absolute time offsets, because of simpler control circuit designs, which can include a simple counter as opposed to having to factor a clock period to determine the delay.

It will be understood that a time shift using a configuration setting can still be knowable to the memory controller to account for when a specific DRAM device, and a specific memory Bank is available for access. By knowing the offsets and the timing of the sending of refresh command 322, the memory controller can calculate which DRAM device is available for access and which one or ones are in refresh. Thus, the memory controller can still issue normal access operations, such as ACT (Activate), RD (Read), and WR (Write) commands to free Ranks or Slices. Staggering the refresh start time and utilizing free memory resources can both mitigate peak power, while also mitigating performance degradation due to command conflicts.

While shown implemented among different DRAM dies within device 300, it will be understood that the implementation of refresh staggering can be accomplished for any group of memory devices. For example, different multichip packages can be delayed relative to each other. As another example, different memory devices can be delayed relative to each other. As another example, as illustrated in FIG. 3, different ranks can be delayed relative to each other.

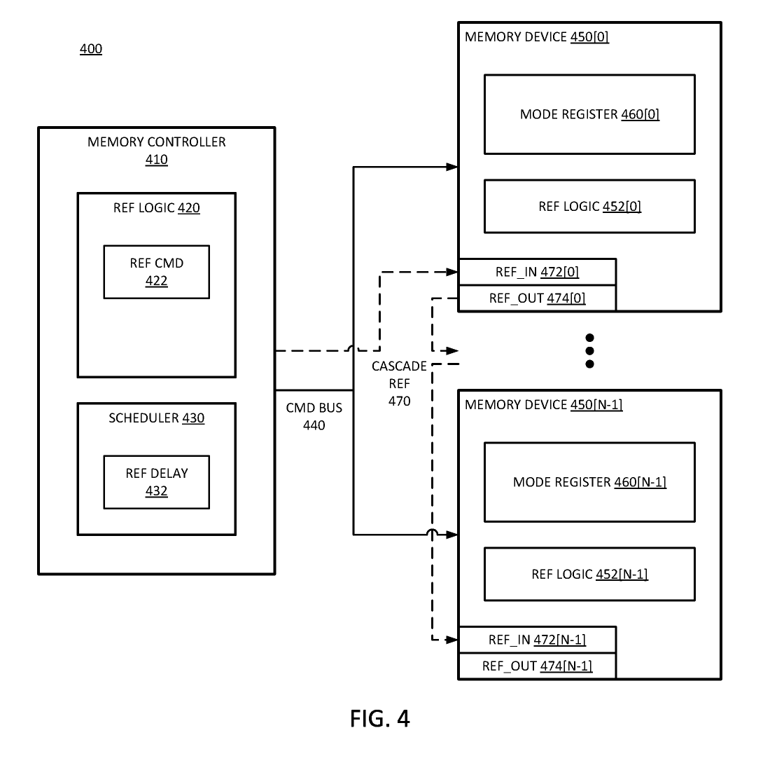

FIG. 4 is a block diagram of an embodiment of a system with refresh staggering by architecture design. System 400 illustrates elements of a memory system, and is one example of an embodiment of system 100 of FIG. 1. System 400 includes memory controller 410 to manage access to, and refresh of, volatile memory devices 450. It will be understood that reference to memory devices 450 is a shorthand referring collectively to the N memory devices 450[0] to 450[N-1] represented in system 400, where N is an integer greater than 1. The N memory devices 450[0] to 450[N-1] respectively include corresponding mode registers 460[0] to 460[N-1] with refresh delay parameters (ref delay param) 462[0] to 462[N-1], and refresh logic 452[0] to 452[N-1], and can all likewise be referred to by the same shorthand explained above. Memory devices 450 are part of a group of memory devices that will be refreshed in response to the same refresh command from memory controller 410.

In one embodiment, memory controller 410 includes refresh logic 420 with refresh command (ref cmd) logic 422. Refresh command logic 422 represents logic to generate refresh commands to send to memory devices 450. In one embodiment, refresh command logic 422 generates all bank refresh commands. In one embodiment, refresh command logic 422 generates per bank refresh commands. In one embodiment, refresh command logic 422 generates all bank and per bank refresh commands.

Memory controller 410 includes controller 430 to schedule commands to send to memory devices 450. Part of scheduling commands to send to the memory devices includes the determination of when to send commands based on when memory devices 450 will be in refresh or executing a refresh operation. In one embodiment, the refresh timing includes the start time of each individual memory device 450, where the memory devices have different refresh delays to start refresh at different times. Thus, scheduler 430 is illustrated to include refresh delay 432, which represents the logic within memory controller 410 to factor the refresh timing offsets of different delays. Based on different delays or offsets, memory device 450[N-1] may not be in refresh at the same time as memory device 450[0]. For example, consider a configuration where memory device 450[0] initiates refresh in response to receipt of a refresh command received from memory controller 410 over command (cmd) bus 440, and then forwards an indication of refresh to memory device 450[N-1] after a delay. Rather than initiating refresh in response to the refresh command, memory device 450[N-1] can initiate refresh in response to the delayed indication from memory device 450[0]. Thus, memory device 450[N-1] initiates refresh some delay period after memory device 450[0].

The architecture of system 400 can provide a delay for initiation for refresh among different memory device 450. For example, memory devices 450 can be coupled together by a cascaded signal line. A cascaded signal line can refer to a signal line that terminates at one memory device, and is then forwarded or extended from that memory device to another device, in a daisy-chain fashion. In one embodiment, system 400 includes logic to introduce a delay along the cascade of signal lines. As illustrated in system 400, at least one signal line labeled as cascade refresh 470 first terminates at memory device 450[0], which then forwards the cascade signal to subsequent memory devices 450 until reaching memory device 450[N-1].

In one embodiment, memory devices 450 include refresh_in logic 472, and refresh_out logic 474. In one embodiment, refresh_in logic 472 and refresh_out logic 474 include logic to introduce a delay into the cascade refresh signal sent to subsequent memory devices. For example, consider a configuration where memory devices 450 receive cascade refresh signal 470, and initiate refresh in response to the signal, and then forward the signal to the subsequent memory device after a period of delay or after completion of the internal refresh operations. Cascade refresh signal 470 can be considered a refresh indication signal cascaded to memory devices 450 or propagated from one memory device to another.

System 400 illustrates command bus 440 coupled to all memory devices 450. In one embodiment, the signal line cascade refresh 470 can be considered part of command bus 440, for example, as an additional signal line or two signal lines (e.g., separate IN and OUT signal lines) in the command bus. Alternatively, cascade refresh 470 can be considered a separate control signal line. Memory devices 450 receive and capture a refresh command from command bus 440, which would traditionally trigger all devices to initiate internal refresh operations. In accordance with system 400, in one embodiment, memory devices 450 do not initiate internal refresh operations in response to the refresh command until seeing a logic value (e.g., either HIGH or LOW, depending on the configuration) on the input signal line of cascade refresh 470. Thus, regardless of the configuration of the rest of the command bus, such as having the command bus deliver commands substantially simultaneously to all memory devices 450, only one or a selected group of memory devices 450 will receive cascade refresh 470 at a time. After initiating refresh, or after a period of delay after initiating refresh, or after completion of refresh, the memory device then outputs the cascade refresh signal 470 to the next memory device, which will then trigger than memory device to initiate internal refresh operations. In one embodiment, only one memory device 450 receives cascade refresh 470 at a time. In one embodiment, multiple memory devices 450 that are part of the same rank receive cascade refresh 470 at substantially the same time.

In one embodiment, memory controller 410 is configured to know the delay that occurs between propagation of cascade refresh 470 from one memory device to another, and thus knows the specific refresh timing for each memory device 450. Memory controller 410 uses such information as refresh delay information 432, which is considered by scheduler 430 in scheduling access transactions to memory devices 450. In one embodiment, memory controller 410 can read timing configuration information from mode registers 460, which can indicate how long a delay will occur between receipt of cascade refresh 470 and sending of the cascade refresh signal to the next memory device. Memory controller 410 can use such information as refresh delay information 432.

It will be understood that refresh logic 420 of memory controller 410 can issue a self-refresh command, which is a command to trigger one or more memory devices 450 to enter a low power state and internally manage refresh operations to maintain valid data. Self-refresh is managed internally by the memory devices, as opposed to external refresh commands managed by memory controller 410. Memory devices 450 perform self-refresh operations based on an internal timing or clock signal, and control the timing and generation of internal refresh commands. External refresh or auto refresh refers to a refresh command from memory controller 410 that triggers memory devices 450 to perform refresh in active operation as opposed to a low power state, and based on a timing or clock signal from memory controller 410, as opposed to an internal clock. Thus, memory devices 450 remain synchronized to the timing of memory controller 410 during external refresh operations. In response to an external refresh command, memory devices 450 generate internal refresh operations in response to the command, and synchronized to external timing. As described herein, the timing control of the internal refresh operations in response to an external refresh command can include the introduction of a delay or timing offset in the initiation of the internal refresh operations. Thus, at least one of memory devices 450 will initiate refresh at an offset relative to at least one other of memory devices 450. In one embodiment, memory devices 450 can introduce a delay or timing offset in the initiation of internal refresh operations in response to a self-refresh command, which can prevent the devices from initiating self-refresh at the same time.

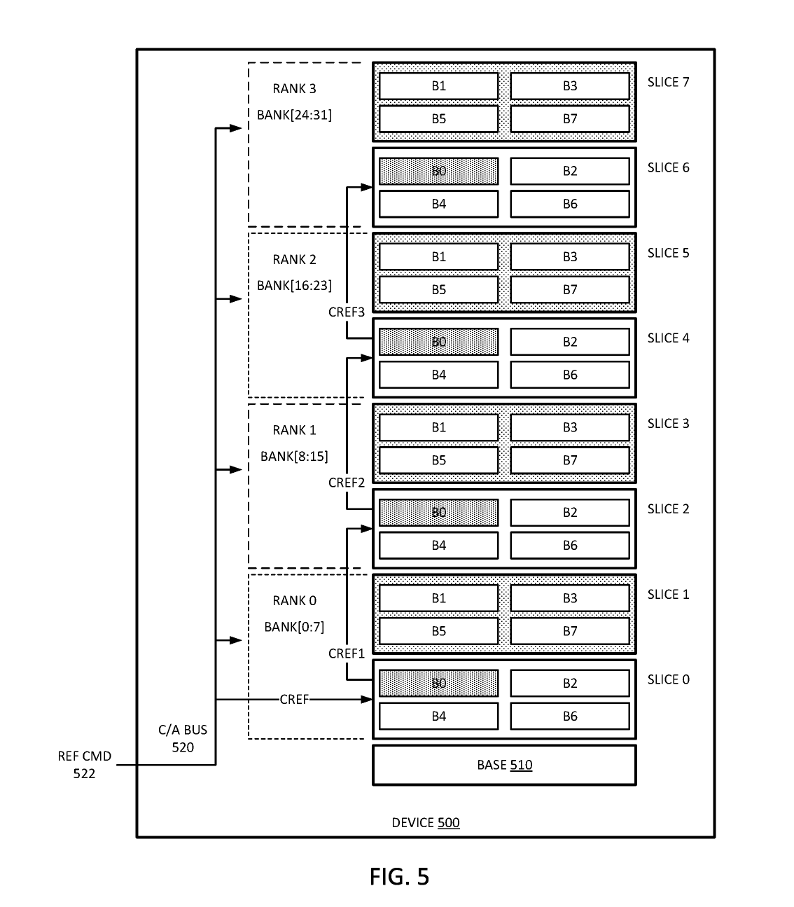

FIG. 5 is a block diagram of an embodiment of an eight stack device that staggers refresh by device architecture. Device 500 provides one example of an embodiment of a multichip package including multiple memory devices. Device 500 can be one example of an implementation of memory devices 450 of system 400. The more specific implementation of device 500 includes an eight-high stack of DRAM devices. Device 500 can be one example of an HBM memory device.

Device 500 includes a semiconductor package that can be mounted to a board or to another substrate. Device 500 includes base 510, which represents a common substrate for the stack of DRAM devices. Typically, base 510 includes interconnections to the externally-facing I/O for device 500. For example, device 500 can include pins or connectors, and traces or other wires or electrical connections to those pins/connectors. The multiple DRAM devices are stacked on base 510, one on top of each other. In device 500 the individual DRAM devices are identified by a designation of “Slices.” Thus, Slices[0:7] represent the eight DRAM devices stacked on base 510. The connections from the package of device 500 reach the individual Slices by means of TSVs (through silicon vias), or other connections, or a combination. A TSV refers to a trace that extends through the entire body of the device. Typically, the DRAM die is thinned to a desired thickness to enable putting TSVs through the device. The TSV can connect the electronics of die to a connector that enables the die to be mounted in a stack. The electronics of the die refers to traces, switches, memory, logic, and other components processed into the die.

For purposes of illustration, device 500 can be considered to have eight Slices organized as four ranks, Ranks[0:3]. Each Rank includes two adjacent Slices, where each Slice is illustrated to have four banks. The four banks are organized across the two Slices as Banks[0:7]; for example, Slice0 includes four Banks identified as B0, B2, B4, and B6, and Slice1 includes four Banks identified as B1, B3, B5, and B7. Thus, Slice 0 includes the even-numbered banks, and Slice1 includes the odd-numbered banks. These bank number will be understood to refer to the eight banks within the Rank. The system-level bank number can be understood as the numbers shown, with an offset of 0, 8, 15, or 24. For example, Slice1 also includes four Banks identified as B0, B2, B4, and B6, and Slice3 includes four Banks identified as B1, B3, B5, and B7. These Banks are Banks[0:7] for Rank1, and are Banks[8:15] for the system. It will be understood that the organization shown and described is not limiting, and is solely for purposes of illustration. Other configurations are possible, with different numbers of Slices, with different numbers of Banks, different numbers of Ranks, different numbers of DRAM devices per Rank, different organization of the Bank designations, or a combination.

As illustrated, Rank0 includes Slices[0:1] with Banks[0:7], Rank1 includes Slices[2:3] with Banks[8:15], Rank2 includes Slices[4:5] with Banks[16:23], and Rank3 includes Slices[6:7] with Banks[24:31]. In one embodiment, Slices[0:7] share command/address (C/A) bus 520, in a multidrop bus configuration, where all devices are coupled to the same signal lines. In such an embodiment, refresh command (ref cmd) 522 received on C/A bus 320 from an associated memory controller (not specifically illustrated) reaches all Slices substantially at the same time, with time differences being only the propagation delay on the signal lines (e.g., TSVs) to the devices further out on the C/A bus.

It will be understood that the representation of C/A bus 520 is illustrated to show that the command and address bus couples to the various Ranks of DRAM devices, which would then all receive refresh command 522 at substantially the same time. A practical implementation of C/A bus 520 would come into device 500 to base 510, and be propagated to Slices[0:7] via stacked connections.

Thus, device 500 illustrates a single refresh trigger for all DRAM devices, which then implement the refresh at different timings. The different timings for device 500 can be controlled by the cascading of a refresh indication signal, from one Slice or Rank to the next. For example, Rank0 with Slices[0:1] receives a refresh indication signal CREF from the memory controller, and initiates internal refresh operations in response to receipt of a refresh command received on C/A bus 520. After a delay period (e.g., after a number of clock cycles, after completion of the internal refresh operations, or after initiation of the internal refresh operations), Rank0 forwards the refresh indication signal by generating signal CREF1 for Rank1 with Slices[2:3]. In response to the CREF1 signal, Rank1 initiates refresh in response to the refresh command received on C/A bus 520. Thus, Slices[2:3] initiate refresh at an offset relative to Slices[0:1] of Rank0. Similarly, in one embodiment, Rank1 generates signal CREF2 for Rank2, and Rank2 generates signal CREF3 for Rank3. The delay or offset between Rank1 and Rank2, and between Rank2 and Rank3 can be the same as that for the delay between Rank0 and Rank1. The consistency of the delay between ranks can enable the memory controller to more accurately schedule memory access transactions based on refresh timing for the different DRAM devices.

It will be understood that DRAM devices include control logic with internal timing protocols for Refresh operations to complete WL operations (e.g., wordline charging) and SA operation (e.g., sense amplifier read and write-back), and then perform a Precharge operation to return the memory resources to a known state. With such internal timings, the DRAM device controller can detect a timing trigger of the cascade refresh indication, and send the trigger to a subsequent DRAM device. Each DRAM device receiving the indication can subsequently trigger the next DRAM device to cause the trigger to propagate to the last DRAM device in the group. It will be understood that such an architecture implementation may require at least two additional signal lines, such as CREFin and CREFout.

In one embodiment, the timing of sending the refresh indication signal is based on internal DRAM device refresh timing, which can enable implementation of the delay without introduction of additional timing generation circuits in the DRAM devices. When a DRAM device waits until the end of its refresh operations before sending the trigger to the next DRAM device, refresh will cascade through the DRAM devices, while refresh operations are completely or almost completely non-overlapping. Even with the cascading refresh operations, the memory controller can calculate the refresh on-going timing for each Rank or Slice, such as based on a tRFC value, a known delay, or other value, or a combination.

It will be understood that a time shift using a configuration setting can still be knowable to the memory controller to account for when a specific DRAM device, and a specific memory Bank is available for access. By knowing the offsets and the timing of the sending of refresh command 522, the memory controller can calculate which DRAM device is available for access and which one or ones are in refresh. Thus, the memory controller can still issue normal access operations, such as ACT (Activate), RD (Read), and WR (Write) commands to free Ranks or Slices. Staggering the refresh start time and utilizing free memory resources can both mitigate peak power, while also mitigating performance degradation due to command conflicts.

While shown implemented among different DRAM dies within device 500, it will be understood that the implementation of refresh staggering can be accomplished for any group of memory devices. For example, different multichip packages can be delayed relative to each other. As another example, different memory devices can be delayed relative to each other. As another example, as illustrated in FIG. 5, different ranks can be delayed relative to each other.

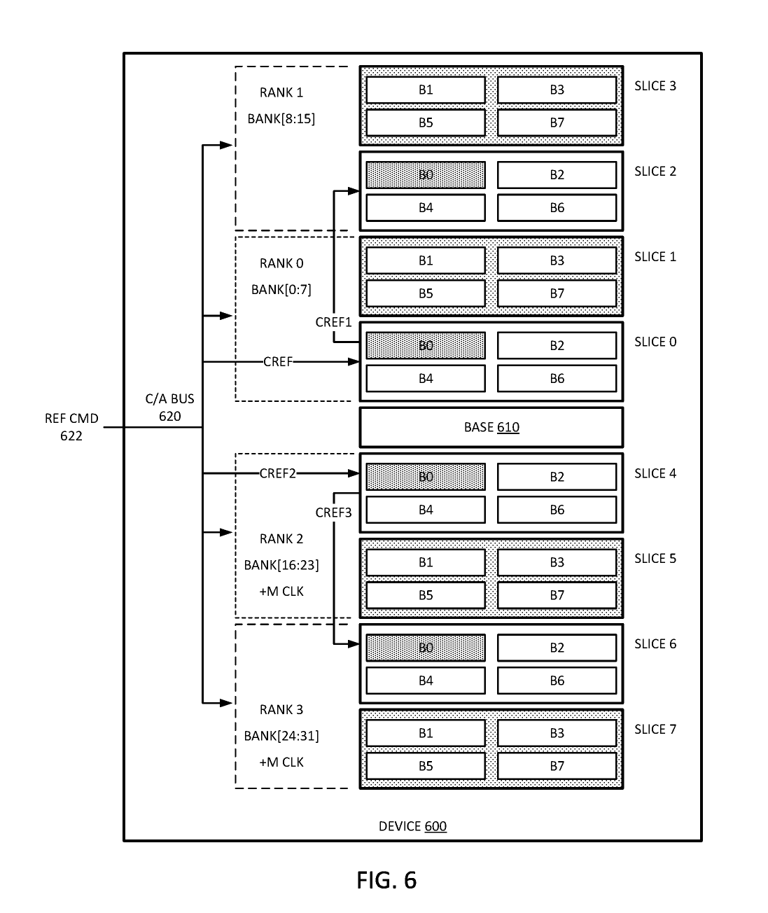

FIG. 6 is a block diagram of an embodiment of an eight stack device that staggers refresh by both device architecture and memory device configuration. Device 600 provides one example of an embodiment of a multichip package including multiple memory devices. Device 600 can be one example of an implementation of memory devices 250 of system 200 and memory devices 450 of system 400. The more specific implementation of device 600 includes an eight-chip package of DRAM devices in split four-high stacks. Device 800 can be one example of an HBM memory device.

Device 600 includes a semiconductor package that can be mounted to a board or to another substrate. Device 600 includes base 610, which represents a common substrate for the stacks of DRAM devices. Typically, base 610 includes interconnections to the externally-facing I/O of the package of device 600. For example, device 600 can include pins or connectors, and traces or other wires or electrical connections to those pins/connectors. The multiple DRAM devices are stacked on base 610, with one stack on one side of base 610, and a second stack on the other side of base 610. In device 600 the individual DRAM devices are identified by a designation of “Slices.” Thus, Slices[0:7] represent the eight DRAM devices or dies stacked on base 610. As illustrated, Slices[0:3] can be mounted on one side, and Slices[4:7] mounted on the other side. As illustrated, the lower number devices are closer to base 610. Other configurations are possible, with different arrangements of the DRAM dies.

The connections from the package of device 600 reach the individual Slices by means of TSVs (through silicon vias), or other connections, or a combination. A TSV refers to a trace that extends through the entire body of the device. Typically, the DRAM die is thinned to a desired thickness to enable putting TSVs through the device. The TSV can connect the electronics of die to a connector that enables the die to be mounted in a stack. The electronics of the die refers to traces, switches, memory, logic, and other components processed into the die.

For purposes of illustration, device 600 can include eight Slices organized as four ranks, Ranks[0:3], with Ranks[0:1] on one side, and Ranks[2:3] on the other side. Each Rank includes two adjacent Slices, where each Slice is illustrated to have four banks. The four banks are organized across the two Slices as Banks[0:7]; for example, Slice0 includes four Banks identified as B0, B2, B4, and B6, and Slice1 includes four Banks identified as B1, B3, B5, and B7. Thus, Slice 0 includes the even-numbered banks, and Slice1 includes the odd-numbered banks. These bank number will be understood to refer to the eight banks within the Rank. The system-level bank number can be understood as the numbers shown, with an offset of 0, 8, 15, or 24. For example, Slice1 also includes four Banks identified as B0, B2, B4, and B6, and Slice3 includes four Banks identified as B1, B3, B5, and B7. These Banks are Banks[0:7] for Rank1, and are Banks[8:15] for the system. It will be understood that the organization shown and described is not limiting, and is solely for purposes of illustration. Other configurations are possible, with different numbers of Slices, with different numbers of Banks, different numbers of Ranks, different numbers of DRAM devices per Rank, different organization of the Bank designations, or a combination.

As illustrated, Rank0 includes Slices[0:1] with Banks[0:7], Rank1 includes Slices[2:3] with Banks[8:15], Rank2 includes Slices[4:5] with Banks[16:23], and Rank3 includes Slices[6:7] with Banks[24:31]. In one embodiment, Slices[0:7] share command/address (C/A) bus 620, in a multidrop bus configuration, where all devices are coupled to the same signal lines. In such an embodiment, refresh command (ref cmd) 622 received on C/A bus 620 from an associated memory controller (not specifically illustrated) reaches all Slices substantially at the same time, with time differences being only the propagation delay on the signal lines (e.g., TSVs) to the devices further out on the C/A bus.

It will be understood that the representation of C/A bus 620 is illustrated to show that the command and address bus couples to the various Ranks of DRAM devices, which would then all receive refresh command 622 at substantially the same time. A practical implementation of C/A bus 620 would come into device 600 to base 610, and be propagated to Slices[0:3] via stacked connections on one side of base 610, and to Slices[4:7] via stacked connections on the other side of base 610. Thus, device 600 illustrates a single refresh trigger for all DRAM devices, which then implement the refresh at different timings. In one embodiment, the DRAM devices of device 600 implement both configuration setting delays, and architectural delays.

With reference to architectural delays, device 600 can include refresh timing control based on the cascading of a refresh indication signal, from one Slice or Rank to the next. For example, Rank0 with Slices[0:1] receives a refresh indication signal CREF from the memory controller, and initiates internal refresh operations in response to receipt of a refresh command received on C/A bus 620. After a delay period (e.g., after a number of clock cycles, after completion of the internal refresh operations, or after initiation of the internal refresh operations), Rank0 forwards the refresh indication signal by generating signal CREF1 for Rank1 with Slices[2:3].

In one embodiment, Rank2 with Slices[4:5] also receives refresh command 622 on C/A bus 620, and receives a refresh signal CREF2. In one embodiment, CREF2 and CREF are the same signal. To the extent the signals are different signals, the memory controller can assert different CREF signals to different Ranks of device 600. In one embodiment, in addition to receipt of CREF2, Rank2 can delay the start of refresh by +M CLK. In one embodiment, Rank3 also delays the start of refresh by +M CLK, but additionally waits for a refresh indication signal, which Rank2 generates as CREF3 to send to Rank3 some delay after initiation of refresh. Thus, Rank2 can receive refresh command 622 at the same time as Rank0, and where Rank0 starts immediately to refresh, Rank2 waits +M CLK. After a delay period, which may be more or less than +M clocks, Rank0 generates CREF1, which triggers Rank1 to initiate refresh.

If the delay period is greater than +M clocks, then Rank2 will initiate refresh operations prior to Rank1. If the delay period is less than +M clocks, Rank1 will initiate refresh prior to Rank2. After +M clocks, Rank2 initiates refresh, and delays another delay period before sending CREF3 to Rank3. Thus, Rank 3 initiates refresh operations after +M clocks, in addition to the delay Rank2 waits to send CREF3. Thus, device 600 implements delay mechanisms similar to those of device 300 of FIG. 3, and device 500 of FIG. 5. It will be understood that modifications can be made to combining the different delay mechanisms. It will be understood that M can be selected to stagger the initiation of refresh by all Ranks, and can be selected in light of knowing the pattern for sending the CREF trigger signals.

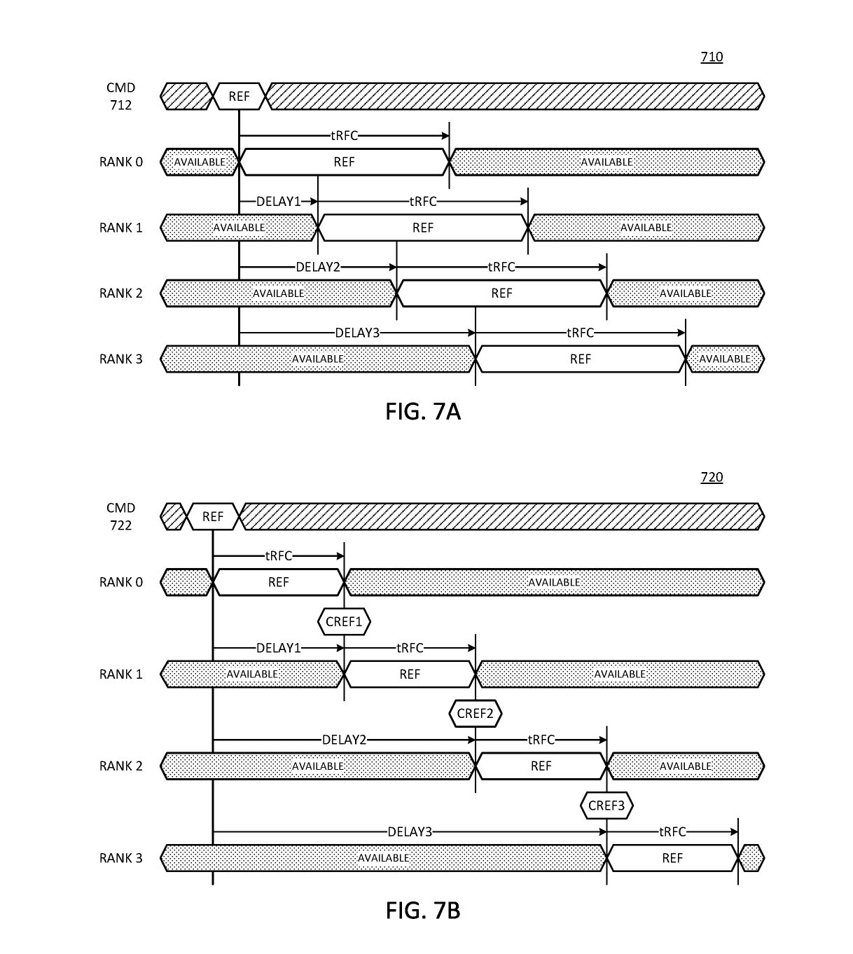

FIG. 7A is a timing diagram of an embodiment of refresh staggering where different ranks initiate refresh offset from each other. Diagram 710 illustrates relative timing offsets for different ranks, which timing offsets can occur in accordance with any embodiment of system 200 of FIG. 2, device 300 of FIG. 3, or device 600 of FIG. 6. Command signal 712 represents a command received on a command bus from a memory controller to a group of memory devices. The shaded portions are “Don't Care,” and can include access commands to available memory devices.

The refresh command of command signal line 712 is to cause the DRAM devices of Ranks[0:3] to perform refresh (which can include an auto refresh or external refresh, or a self-refresh command). Ranks[0:3] can include multiple DRAM devices, or multiple slices in accordance with previous examples. It will be understood that more or fewer ranks could be used, and can operate in accordance with what is illustrated in diagram 710. For purposes of diagram 710, consider that all Ranks[0:3] are available (the shaded areas in the lines representing the operation of the Ranks) when the refresh command is received. Traditionally, in response to receipt of the refresh command, all Ranks[0:3] would initiate refresh. In accordance with staggered refresh start, one Rank initiates prior to another, which can continue through all Ranks. As illustrated, Rank0 initiates refresh operations in response to the refresh command, which continues for tRFC, or the time between refresh and the first valid command. In the time tRFC, Rank0 will complete the refresh of a row of memory, or multiple rows if it is configured to refresh multiple rows in response to a single refresh command.

After some period Delay1, Rank1 initiates refresh and will be in refresh for tRFC. After some period Delay2, Rank2 initiates refresh and will be in refresh for tRFC. After some period Delay3, Rank3 initiates refresh and will be in refresh for tRFC. In one embodiment, Delay1, Delay2, and Delay3 are caused by configuration settings programmed into the memory devices of Ranks[0:3]. For example, consider an implementation where the memory controller sets time shifts with MRS settings, and sets Rank0 to a delay of +0 CLK, Rank1 to a delay of +M CLK, Rank2 to a delay of +2M CLK, and Rank3 to a delay of +3M CLK, where M is an integer. In previous examples, a value of M=10 was used to illustrate an example of initiating refresh operations separated by 10 clocks.

It will be understood that when a Rank is not in refresh, it is typically available for memory access operations. Thus, the areas outside of the refresh time are shaded and labeled as “Available.” The memory controller will know the timing of refresh, whether because it sets the refresh delays with configuration setting commands, or by knowing the refresh trigger signal pattern, or being configured with other information, or a combination. Thus, the memory controller can schedule access transactions to available Ranks while other ranks are in refresh.

FIG. 7B is a timing diagram of another embodiment of refresh staggering where different ranks initiate refresh offset from each other. Diagram 720 illustrates relative timing offsets for different ranks, which timing offsets can occur in accordance with any embodiment of system 400 of FIG. 4, device 500 of FIG. 5, or device 600 of FIG. 6. Command signal 722 represents a command received on a command bus from a memory controller to a group of memory devices. The shaded portions are “Don't Care,” and can include access commands to available memory devices.

The refresh command of command signal line 712 is to cause the DRAM devices of Ranks[0:3] to perform refresh (which can include an auto refresh or external refresh, or a self-refresh command). Ranks[0:3] can include multiple DRAM devices, or multiple slices in accordance with previous examples. It will be understood that more or fewer ranks could be used, and can operate in accordance with what is illustrated in diagram 710. For purposes of diagram 710, consider that all Ranks[0:3] are available (the shaded areas in the lines representing the operation of the Ranks) when the refresh command is received. Traditionally, in response to receipt of the refresh command, all Ranks[0:3] would initiate refresh. In accordance with staggered refresh start, one Rank initiates prior to another, which can continue through all Ranks. As illustrated, Rank0 initiates refresh operations in response to the refresh command, which continues for tRFC, or the time between refresh and the first valid command. In the time tRFC, Rank0 will complete the refresh of a row of memory, or multiple rows if it is configured to refresh multiple rows in response to a single refresh command.

In one embodiment, Delay1, Delay2, and Delay3 are caused by cascading a trigger signal from one memory device to the next. In one embodiment, a Rank receives a refresh trigger signal (e.g., CREF), and executes refresh operations in accordance with the refresh command and the refresh trigger. It then sends a similar trigger to a subsequent memory device (e.g., one physically farther from the memory controller). In one embodiment, a Rank sends a trigger to the subsequent Rank after completion of refresh. Thus, using diagram 710 as an example, Rank0 could perform refresh in response to a triggering edge of the refresh command. Rank1 could receive the refresh command, but not immediately initiate refresh. In one embodiment, in response to completion of refresh operations in Rank0, Rank0 sends a refresh trigger to Rank1. Thus, Delay1 can be approximately equal to rRFC. Continuing with the same pattern, assume that Rank1 sends a refresh trigger to Rank2 in response to its completion of internal refresh operations. Thus, Delay2 can be approximately equal to 2*tRFC, and so forth.

It will be understood that when a Rank is not in refresh, it is typically available for memory access operations. Thus, the areas outside of the refresh time are shaded and labeled as “Available.” The memory controller will know the timing of refresh, whether because it sets the refresh delays with configuration setting commands, or by knowing the refresh trigger signal pattern, or being configured with other information, or a combination. Thus, the memory controller can schedule access transactions to available Ranks while other ranks are in refresh.

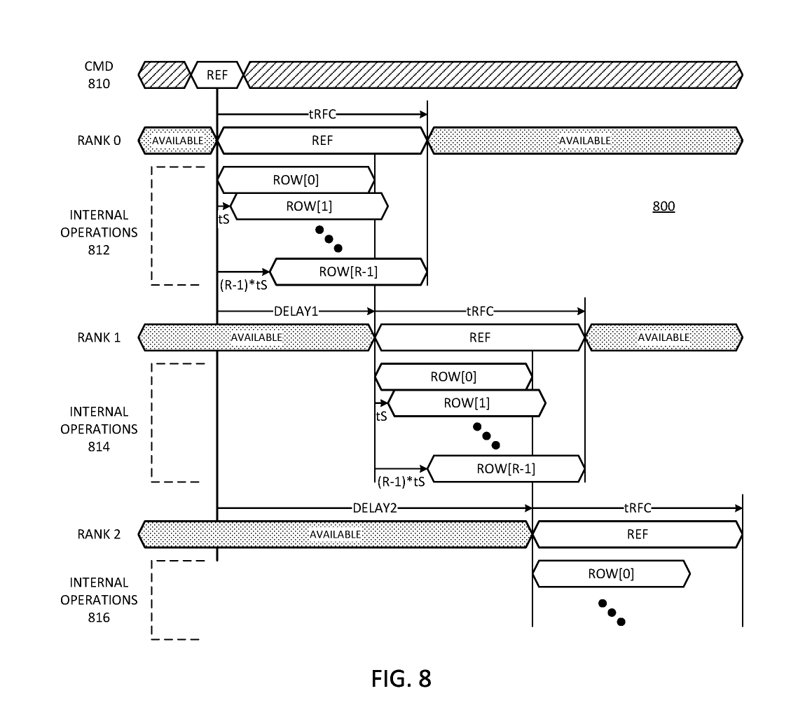

FIG. 8 is a timing diagram of an embodiment of refresh staggering where different ranks initiate refresh offset from each other, and internally the ranks stagger row refresh. Diagram 800 is a timing diagram that illustrates details of one embodiment of internal operations of refresh. Diagram 800 can be one example of an embodiment of a timing diagram in accordance with diagram 700. Diagram 800 is similar to diagram 700, and the discussion of diagram 700 applies equally to diagram 800. Diagram further illustrates an embodiment of internal handling of refresh operations when a Rank is in refresh.

It will be understood that the timing parameter tRFC is traditionally a row refresh cycle time, and more specifically defines a time between a refresh command and a next valid command. Traditionally a DRAM device would refresh a single row in response to a refresh command. As memory densities have increased, DRAM devices commonly refresh multiple rows in response to a single refresh command. For example, a DRAM device may refresh 4 or 8 rows in response to a single refresh command. Such an increase in the number of rows refreshed may also increase the maximum power peak. Thus, a DRAM device may internally stagger the refresh of multiple rows that are refreshed in response to the refresh command. If R rows are to be refreshed in response to a refresh command, the DRAM controller can cause a delay of tS or stagger time between the start of refresh of the R rows, as illustrated by internal operations 812 and internal operations 814. Internal operations 812 refer to the internal operations of DRAM devices of Rank0, and internal operations 814 refer to the internal operations of DRAM device of Rank1.

As illustrated, the timing parameter tRFC still refers to the time between refresh and the next valid command, but in an implementation where the DRAM devices refresh multiple rows and stagger the start of refresh of the rows, the time tRFC refers to the time is takes to refresh all rows, which can be a time longer than the time to refresh a single row. While staggering is illustrated for all R rows, it will be understood that the DRAM device can stagger the rows in groups, in accordance with a desired or acceptable peak power. For example, Row[0] and Row[1] could be started together, and following a delay of tS, Row[2] and Row[3] could be refreshed. Other implementations are possible. Thus, the delay for the last Row[R-1] can be a delay of (R-1)*tS. It will be understood that the relative timings are not necessarily drawn to scale, but are for illustration purposes only of the principles of staggering the initiation of refresh for different memory devices, and the staggering of refresh of rows internally within the memory devices.

Delay1 can be a time period set either by configuration setting or by architecture (e.g., signaling a refresh trigger), or a combination to stagger the start of refresh of Rank1. Delay2 is similar to Delay1, for initiation of refresh of Rank2. In one embodiment, it is advantageous to wait for a subsequent rank to initiate refresh until a last row of the previous rank or memory device initiates refresh. Thus, Delay1 can be set to a time after the start of refresh of all R Rows of Rank0, and may be a time at least as long as tRFC to allow all Rows to be refreshed.

Internal operations 812 illustrates the staggering of row refresh within Rank0. Internal operations 814 illustrates the staggering of row refresh within Rank1. Delay1 and Delay2 illustrate the staggering of refresh of the Ranks. Delay2 is illustrated to start the refresh of Rank2, but the internal operations of Rank2 are not illustrated for simplicity in the drawing. It will be understood that the internal operations of Rank2 will be similar to internal operations 812 and 814, as is suggested by showing the start of internal operations 816 for Rank2.

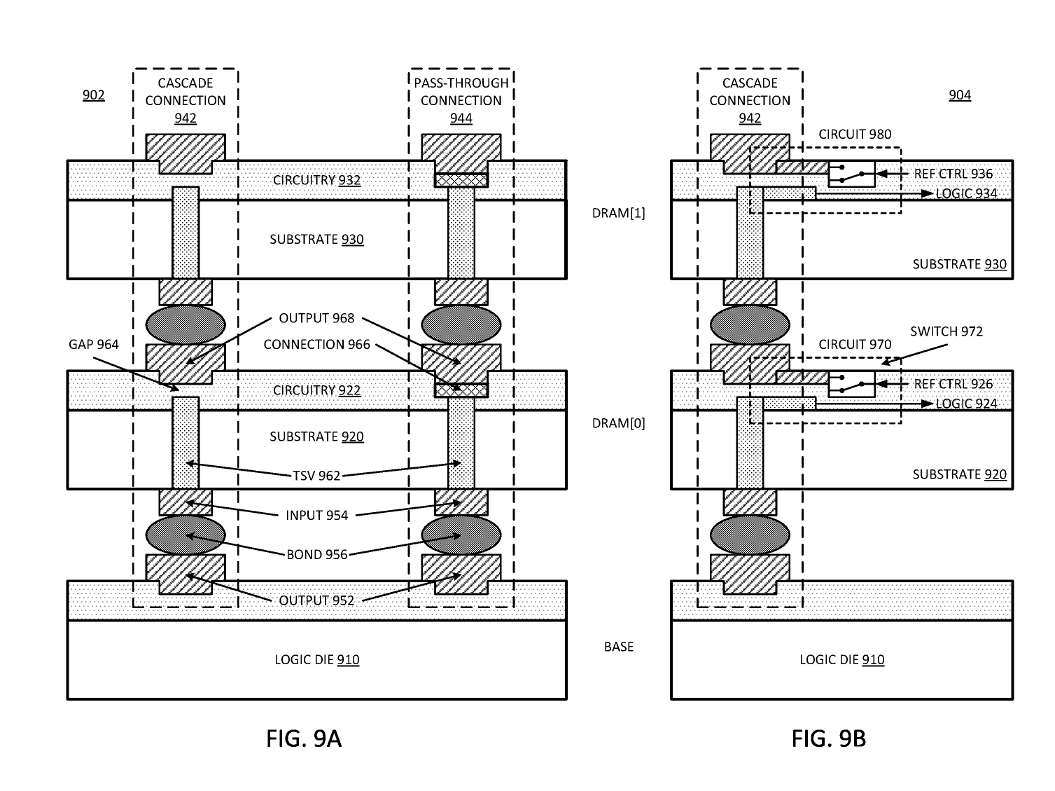

FIGS. 9A-9B are representations of an embodiment of a signal connection for a device architecture to enable staggering refresh in a stack of memory devices. View 902 represents a cross section of a circuit stack, and is not necessarily drawn to scale. The illustration of view 902 shows the difference between cascade connection 942 (a selective connection) and pass-through connection 944. View 904 represents the same circuit stack from a different perspective to show a cross section representation of the circuitry that makes the connection of selective connection 942.

Connection 944 can be, for example, a power connection or a multidrop bus connection or other connection that should pass from the base up through all DRAM devices. Connection 942 can be a trigger signal connection, where a signal receive at one device is not immediately passed through to the next DRAM device. Rather than pass straight through, cascade connection is selectively connected. As illustrated, the same physical TSV connection location can enable a cascade connection or a pass-through connection.

Logic die 910 can be a base substrate, for example, in a multichip package (MCP). The slightly shaded portion of logic die 910 represents the area of the die in which logic, circuitry, interconnections, or other circuit elements or a combination, are processed into or onto the die. Again, the drawings are not intended to be to scale, and various components (such as the memory) are not illustrated to allow for a simpler drawing. Logic die 910 will include connections to a package (not specifically illustrated), and can include outputs 952 to substrate 920 of DRAM[0]. The shaded portion of DRAM[0] is labeled as circuitry 922, and represents the processed portion of the die where circuitry and internal interconnections are processed. DRAM[1] similarly includes substrate 930 with circuitry 932.

Logic die 910 includes outputs 952 to electrically connect to inputs 954 of substrate 920 via bonds 956. Bonds 956 represent a solder or other connection to electrically connect inputs 954 to outputs 952, both of which are electrically conductive. Input 954 of connection 942 can be referred to as CREFin in an embodiment where the connection is for a refresh trigger signal. While not specifically labeled, substrate 920 of DRAM[0] includes an output similar to output 952 of logic die 910, and can be referred to as CREFout for the embodiment where the connection is for the refresh trigger signal. In one embodiment, there are mechanical connections between the dies in addition to the electrical connections. The electrical connections extend through substrate 920 via TSVs 962. TSVs 962 connect from input 954 to one or more components of circuitry 922.

As illustrated in view 904, in one embodiment, circuitry 922 can include logic 924, which receives the input refresh trigger signal. Logic 924 can cause the refresh of memory resources in response to the trigger signal. In one embodiment, logic 924 can also determine when to send the signal to DRAM[1]. In one embodiment, the logic generates a refresh control signal 926, which, for example, can cause switch 972 of circuit 970 to connect to the output from substrate 920. The switch can then produce the refresh trigger signal for DRAM[1]. It will be understood that certain circuit elements are not shown. Additionally, switch 972 can be considered representative of the ability to send a signal to DRAM[1], and can be a driver or other circuitry. Circuit 970 represents the input of a refresh trigger, and the cascaded output of the signal to the next DRAM die.

While not specifically labeled, substrate 920 connects to substrate 930 in the same or a similar way as logic die 910 connects to substrate 920. While the interconnection is not specifically labeled, substrate 930 includes similar input and output circuitry. Substrate 930 includes circuit 980, which can be similar to circuit 970 of substrate 920. Circuitry 932 of DRAM[1] can likewise include logic 934 and refresh control 936.

View 902 illustrates a difference in cascade connection 942 versus pass-through connection 944. In cascade connection 942, TSV 942 can connect to one or more elements of circuitry 922, but does not pass through to output 968, which connects to substrate 930. Instead, cascade connection 942 includes gap 964, so that TSV 962 does not electrically contact output 968. Thus, connection to output 968 of TSV 962 for connection 942 can only be made with circuitry 922. In contrast, pass-through connection 944 includes connection 966, which directly connects TSV 962 to output 968 for connection 944.

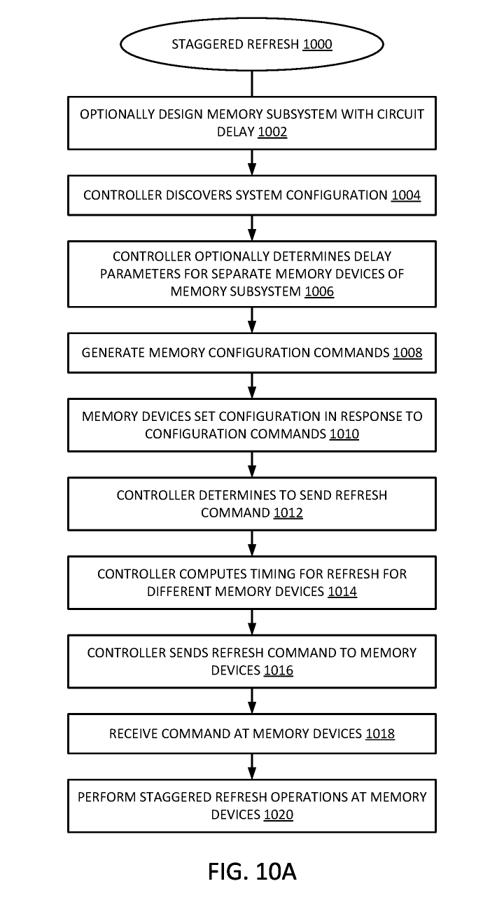

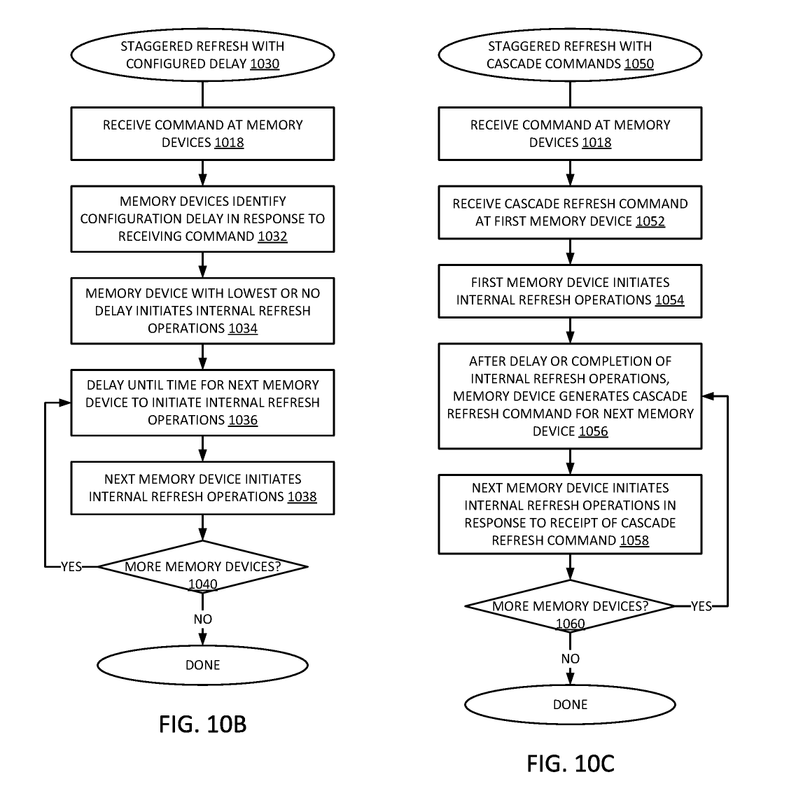

FIG. 10A is a flow diagram of an embodiment of a process for staggering memory device refresh. Process 1000 for performing staggered refresh can be performed by a memory controller and an associated group of memory devices, as set out below. In accordance with what is described above, refresh staggering can be accomplished through the use of a refresh trigger signal, or a refresh delay configuration setting, or a combination. The staggered refresh operations can be in accordance with embodiments described above.

The use of a refresh trigger signal may require additional signal lines or connectors to convey the signal. In one embodiment, a device manufacturer designs a memory subsystem or a memory device (such as an HBM or other MCP) with circuit delay hardware, 1002. In addition to separate signal lines, the circuitry for the delay signal can include transceiver hardware and logic to operate in response to a received signal and logic to generate an output signal.

In an operational memory subsystem, the memory controller discovers the system configuration, 1004. Discovery of the system configuration can include determining the layout and delays involved in signaling, the types of memory devices, and the standard timing parameters for the devices. In one embodiment, the memory controller determines one or more delay parameters to set for separate memory devices of the memory subsystem that will receive the same external refresh commands, 1006. Such a determination can be made, for example, when refresh staggering will occur via configuration setting.

The use of a refresh delay configuration setting will require the use of an additional configuration setting in the memory devices. Such a configuration setting can be set by the memory controller, such as through a configuration settings command (e.g., MRS), or by preprogramming the memory devices. In one embodiment, the memory controller sets the configuration settings, and generates memory configuration commands to send to the devices to set different delays, 1008, such as setting configuration registers. In response to receiving the configuration setting commands, the memory devices set the configuration, 1010.

In one embodiment, the memory controller determines to send a refresh command, 1012. Such a refresh command will be in accordance with refresh needs of the memory devices in active operation, after delay settings are configured, and after delay parameters are known by the memory controller. Based on knowing the delay parameters, the memory controller can compute timing for refresh for the different memory devices, 1014. Thus, the memory controller can know when individual memory devices of the group will be performing refresh, and when individual memory devices are available for memory access operations.

The memory controller sends the command simultaneously to multiple memory devices of a group, 1016. The memory devices receive the command, 1018. In one embodiment, all memory devices receive the command at the same time. In one embodiment, the memory devices receive the refresh command at the same time, but receive refresh trigger signals at different times. In one embodiment, the memory devices receive the refresh command at the same time and initiate refresh operations at different times. Thus, the memory devices initiate refresh operations in a staggered fashion in response to the refresh command, 1020. Being staggered, it will be understood that one device will initiate refresh, and one or more other memory devices do not yet initiate refresh operations. Rather, the system delays refresh operations for the next memory device. The memory devices thus initiate refresh with a timing offset relative to at least one other memory device. Such a pattern of execution of refresh operations and delaying for a next memory device can cascade through all memory devices of the group. Two non-limiting examples of staggering refresh start are provided below in FIGS. 10B and 10C.

FIG. 10B is a flow diagram of an embodiment of a process for staggering refresh start by configuration settings. Process 1030 illustrates staggering refresh with a configured delay. The memory devices receive the refresh command from the memory controller, 1018 from FIG. 10A. In one embodiment, the memory devices identify a configuration delay setting in response to receiving the refresh command, 1032. The configuration setting indicates what delay, if any, is configured for the memory device to wait prior to initiating refresh. The memory with the lower or no delay initiates internal refresh operations first, 1034. The memory devices delay until the delay passes and it is time for the next memory device to initiate internal refresh operations, 1036. After the delay, the next memory device initiates the internal refresh operations, 1038. If there are still more memory devices to refresh, 1040 YES branch, the cycle of refreshing one memory device, delaying, and then initiating in the next memory device continues. If there are no more memory devices to refresh, 1040 NO branch, the refresh operations are complete for that refresh command.

FIG. 10C is a flow diagram of an embodiment of a process for staggering refresh start by a cascade refresh signal. Process 1050 illustrates staggering refresh with cascaded refresh commands. The memory devices receive the refresh command from the memory controller, 1018 from FIG. 10A. In one embodiment, the memory device physically closest to the memory controller receives a cascade refresh command or other refresh indication or refresh trigger, 1052. In one embodiment, for a memory device to initiate refresh, it requires receipt of a valid refresh command, and receipt of a valid refresh trigger signal. Thus, the first memory device initiates internal refresh operations in response to receipt of the refresh command and the cascade refresh signal, 1054. The first memory device will generate a cascade refresh signal to pass to the next memory device. In one embodiment, the memory device generates the signal in response to a delay period. In one embodiment, the memory device generates the signal in response to completion of internal refresh operations. Thus, after a delay period or after completion of internal refresh operations, the memory device generates a cascade refresh command for the next memory device, 1056. In response to receipt of the cascade refresh command, the next memory device initiates the internal refresh operations, 1058. If there are still more memory devices to refresh, 1060 YES branch, the cycle of refreshing one memory device, delaying and generating a cascade refresh signal, and then initiating in the next memory device continues. If there are no more memory devices to refresh, 1060 NO branch, the refresh operations are complete for that refresh command.

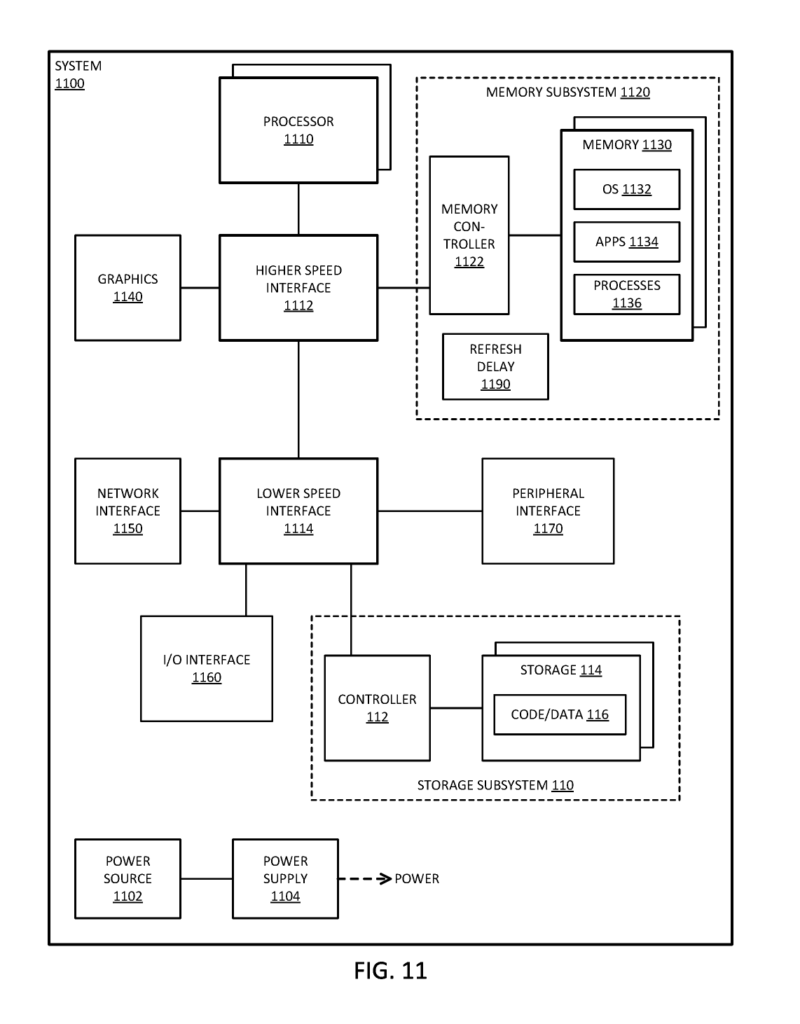

FIG. 11 is a block diagram of an embodiment of a computing system in which refresh staggering can be implemented. System 1100 represents a computing device in accordance with any embodiment described herein, and can be a laptop computer, a desktop computer, a tablet computer, a server, a gaming or entertainment control system, a scanner, copier, printer, routing or switching device, embedded computing device, a smartphone, a wearable device, an internet-of-things device or other electronic device.

System 1100 includes processor 1110, which provides processing, operation management, and execution of instructions for system 1100. Processor 1110 can include any type of microprocessor, central processing unit (CPU), graphics processing unit (GPU), processing core, or other processing hardware to provide processing for system 1100, or a combination of processors. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one embodiment, system 1100 includes interface 1112 coupled to processor 1110, which can represent a higher speed interface or a high throughput interface for system components that needs higher bandwidth connections, such as memory subsystem 1120 or graphics interface components 1140. Interface 1112 can represent a “north bridge” circuit, which can be a standalone component or integrated onto a processor die. Where present, graphics interface 1140 interfaces to graphics components for providing a visual display to a user of system 1100. In one embodiment, graphics interface 1140 can drive a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. In one embodiment, the display can include a touchscreen display. In one embodiment, graphics interface 1140 generates a display based on data stored in memory 1130 or based on operations executed by processor 1110 or both. In one embodiment, graphics interface 1140 generates a display based on data stored in memory 1130 or based on operations executed by processor 1110 or both.

Memory subsystem 1120 represents the main memory of system 1100, and provides storage for code to be executed by processor 1110, or data values to be used in executing a routine. Memory subsystem 1120 can include one or more memory devices 1130 such as read-only memory (ROM), flash memory, one or more varieties of random access memory (RAM) such as DRAM, or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one embodiment, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”).

In one embodiment, system 1100 includes interface 1114, which can be coupled to interface 1112. Interface 1114 can be a lower speed interface than interface 1112. In one embodiment, interface 1114 can be a “south bridge” circuit, which can include standalone components and integrated circuitry. In one embodiment, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can exchange data with a remote device, which can include sending data stored in memory or receiving data to be stored in memory.

In one embodiment, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one embodiment, system 1100 includes storage subsystem 1180 to store data in a nonvolatile manner. In one embodiment, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, or optical based disks, or a combination. Storage 1184 holds code or instructions and data 1186 in a persistent state (i.e., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (i.e., the value or state of the data is indeterminate if power is interrupted to system 1100). In one embodiment, storage subsystem 1180 includes controller 1182 to interface with storage 1184. In one embodiment controller 1182 is a physical part of interface 1114 or processor 1110, or can include circuits or logic in both processor 1110 and interface 1114.

Power source 1102 provides power to the components of system 1100. More specifically, power source 1102 typically interfaces to one or multiple power supplies 1104 in system 1102 to provide power to the components of system 1100. In one embodiment, power supply 1104 includes an AC to DC (alternating current to direct current) adapter to plug into a wall outlet. Such AC power can be renewable energy (e.g., solar power) power source 1102. In one embodiment, power source 1102 includes a DC power source, such as an external AC to DC converter. In one embodiment, power source 1102 or power supply 1104 includes wireless charging hardware to charge via proximity to a charging field. In one embodiment, power source 1102 can include an internal battery or fuel cell source.

In one embodiment, memory subsystem 1120 includes multiple volatile memory devices 1130, which are refreshed as a group. More specifically, memory controller 1122 sends a refresh command to refresh multiple memory devices 1130. In one embodiment, system 1100 includes refresh delay 1190, which represents one or more mechanisms to introduce timing offsets or stagger refresh operations of one memory device relative to another, in accordance with any embodiment described herein. In one embodiment, memory controller 1122 sets a configuration setting of different memory devices 1130 to cause the memory devices to delay initiation of refresh operations in response to receipt of a refresh command. In one embodiment, memory devices 1130 cascade refresh indication signals after a delay period or after completion of refresh. Thus, one memory device will initiate and possibly complete refresh prior to signaling a subsequent memory device to initiate refresh.

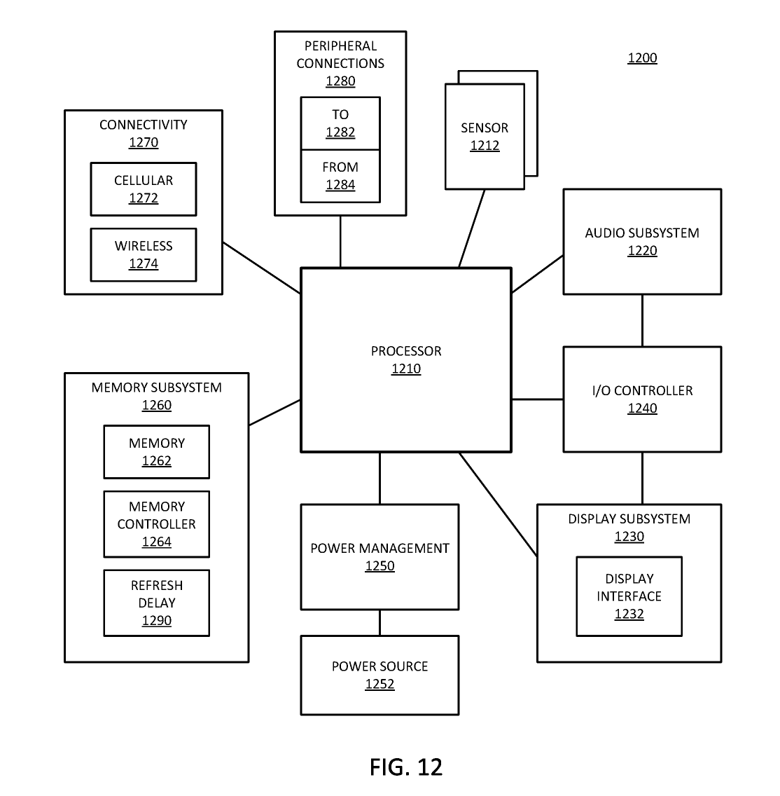

FIG. 12 is a block diagram of an embodiment of a mobile device in which refresh staggering can be implemented. Device 1200 represents a mobile computing device, such as a computing tablet, a mobile phone or smartphone, a wireless-enabled e-reader, wearable computing device, an internet-of-things device or other mobile device, or an embedded computing device. It will be understood that certain of the components are shown generally, and not all components of such a device are shown in device 1200.

Device 1200 includes processor 1210, which performs the primary processing operations of device 1200. Processor 1210 can include one or more physical devices, such as microprocessors, application processors, microcontrollers, programmable logic devices, or other processing means. The processing operations performed by processor 1210 include the execution of an operating platform or operating system on which applications and device functions are executed. The processing operations include operations related to I/O (input/output) with a human user or with other devices, operations related to power management, operations related to connecting device 1200 to another device, or a combination. The processing operations can also include operations related to audio I/O, display I/O, or other interfacing, or a combination. Processor 1210 can execute data stored in memory. Processor 1210 can write or edit data stored in memory.

In one embodiment, system 1200 includes one or more sensors 1212. Sensors 1212 represent embedded sensors or interfaces to external sensors, or a combination. Sensors 1212 enable system 1200 to monitor or detect one or more conditions of an environment or a device in which system 1200 is implemented. Sensors 1212 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1212 can also include sensors for biometric systems such as fingerprint recognition systems, face detection or recognition systems, or other systems that detect or recognize user features. Sensors 1212 should be understood broadly, and not limiting on the many different types of sensors that could be implemented with system 1200. In one embodiment, one or more sensors 1212 couples to processor 1210 via a frontend circuit integrated with processor 1210. In one embodiment, one or more sensors 1212 couples to processor 1210 via another component of system 1200.

In one embodiment, device 1200 includes audio subsystem 1220, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into device 1200, or connected to device 1200. In one embodiment, a user interacts with device 1200 by providing audio commands that are received and processed by processor 1210.

Display subsystem 1230 represents hardware (e.g., display devices) and software components (e.g., drivers) that provide a visual display for presentation to a user. In one embodiment, the display includes tactile components or touchscreen elements for a user to interact with the computing device. Display subsystem 1230 includes display interface 1232, which includes the particular screen or hardware device used to provide a display to a user. In one embodiment, display interface 1232 includes logic separate from processor 1210 (such as a graphics processor) to perform at least some processing related to the display. In one embodiment, display subsystem 1230 includes a touchscreen device that provides both output and input to a user. In one embodiment, display subsystem 1230 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. In one embodiment, display subsystem includes a touchscreen display. In one embodiment, display subsystem 1230 generates display information based on data stored in memory or based on operations executed by processor 1210 or both.

I/O controller 1240 represents hardware devices and software components related to interaction with a user. I/O controller 1240 can operate to manage hardware that is part of audio subsystem 1220, or display subsystem 1230, or both. Additionally, I/O controller 1240 illustrates a connection point for additional devices that connect to device 1200 through which a user might interact with the system. For example, devices that can be attached to device 1200 might include microphone devices, speaker or stereo systems, video systems or other display device, keyboard or keypad devices, or other I/O devices for use with specific applications such as card readers or other devices.

As mentioned above, I/O controller 1240 can interact with audio subsystem 1220 or display subsystem 1230 or both. For example, input through a microphone or other audio device can provide input or commands for one or more applications or functions of device 1200. Additionally, audio output can be provided instead of or in addition to display output. In another example, if display subsystem includes a touchscreen, the display device also acts as an input device, which can be at least partially managed by I/O controller 1240. There can also be additional buttons or switches on device 1200 to provide I/O functions managed by I/O controller 1240.

In one embodiment, I/O controller 1240 manages devices such as accelerometers, cameras, light sensors or other environmental sensors, gyroscopes, global positioning system (GPS), or other hardware that can be included in device 1200, or sensors 1212. The input can be part of direct user interaction, as well as providing environmental input to the system to influence its operations (such as filtering for noise, adjusting displays for brightness detection, applying a flash for a camera, or other features).

In one embodiment, device 1200 includes power management 1250 that manages battery power usage, charging of the battery, and features related to power saving operation. Power management 1250 manages power from power source 1252, which provides power to the components of system 1200. In one embodiment, power source 1252 includes an AC to DC (alternating current to direct current) adapter to plug into a wall outlet. Such AC power can be renewable energy (e.g., solar power, motion based power). In one embodiment, power source 1252 includes only DC power, which can be provided by a DC power source, such as an external AC to DC converter. In one embodiment, power source 1252 includes wireless charging hardware to charge via proximity to a charging field. In one embodiment, power source 1252 can include an internal battery or fuel cell source.

Memory subsystem 1260 includes memory device(s) 1262 for storing information in device 1200. Memory subsystem 1260 can include nonvolatile (state does not change if power to the memory device is interrupted) or volatile (state is indeterminate if power to the memory device is interrupted) memory devices, or a combination. Memory 1260 can store application data, user data, music, photos, documents, or other data, as well as system data (whether long-term or temporary) related to the execution of the applications and functions of system 1200. In one embodiment, memory subsystem 1260 includes memory controller 1264 (which could also be considered part of the control of system 1200, and could potentially be considered part of processor 1210). Memory controller 1264 includes a scheduler to generate and issue commands to control access to memory device 1262.

Connectivity 1270 includes hardware devices (e.g., wireless or wired connectors and communication hardware, or a combination of wired and wireless hardware) and software components (e.g., drivers, protocol stacks) to enable device 1200 to communicate with external devices. The external device could be separate devices, such as other computing devices, wireless access points or base stations, as well as peripherals such as headsets, printers, or other devices. In one embodiment, system 1200 exchanges data with an external device for storage in memory or for display on a display device. The exchanged data can include data to be stored in memory, or data already stored in memory, to read, write, or edit data.

Connectivity 1270 can include multiple different types of connectivity. To generalize, device 1200 is illustrated with cellular connectivity 1272 and wireless connectivity 1274. Cellular connectivity 1272 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 1274 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1280 include hardware interfaces and connectors, as well as software components (e.g., drivers, protocol stacks) to make peripheral connections. It will be understood that device 1200 could both be a peripheral device (“to” 1282) to other computing devices, as well as have peripheral devices (“from” 1284) connected to it. Device 1200 commonly has a “docking” connector to connect to other computing devices for purposes such as managing (e.g., downloading, uploading, changing, synchronizing) content on device 1200. Additionally, a docking connector can allow device 1200 to connect to certain peripherals that allow device 1200 to control content output, for example, to audiovisual or other systems.

In addition to a proprietary docking connector or other proprietary connection hardware, device 1200 can make peripheral connections 1280 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one embodiment, memory subsystem 1260 includes multiple volatile memory devices 1262, which are refreshed as a group. More specifically, memory controller 1264 sends a refresh command to refresh multiple memory devices 1262. In one embodiment, system 1200 includes refresh delay 1290, which represents one or more mechanisms to introduce timing offsets or stagger refresh operations of one memory device relative to another, in accordance with any embodiment described herein. In one embodiment, memory controller 1264 sets a configuration setting of different memory devices 1262 to cause the memory devices to delay initiation of refresh operations in response to receipt of a refresh command. In one embodiment, memory devices 1262 cascade refresh indication signals after a delay period or after completion of refresh. Thus, one memory device will initiate and possibly complete refresh prior to signaling a subsequent memory device to initiate refresh.

In one aspect, a memory device includes: command interface logic to receive a command to trigger refresh of the memory device, wherein the memory device is one of multiple memory devices to be refreshed in response to a refresh command from a memory controller; and refresh logic to refresh the memory device in response to receipt of the command, including to initiate refresh with a timing offset relative to at least one other of the multiple memory devices.

In one embodiment, the memory device comprises a memory die. In one embodiment, the memory die comprises one of multiple dies in a stack of memory dies. In one embodiment, the multiple memory device comprise dynamic random access memory (DRAM) devices compliant with a high bandwidth memory (HBM) standard. In one embodiment, further comprising: a mode register to store a configuration setting to indicate a delay for initiation of the refresh. In one embodiment, the command interface logic is to receive the refresh command from the memory controller and delay initiation of the refresh in accordance with the configuration setting. In one embodiment, the multiple memory devices include different configuration settings to indicate different delays. In one embodiment, the command interface logic is to receive an indication from the at least one other memory device, wherein the at least one other memory device is to provide the indication after initiation of refresh of the at least one other memory device, to initiate refresh of the memory devices in sequence. In one embodiment, after initiation comprises after completion of the refresh. In one embodiment, the refresh of the memory device includes refresh of a determined number of multiple rows in response to the trigger. In one embodiment, refresh of the multiple rows comprises initiation of refresh of the multiple rows in sequence, with initiation timing offset relative to each other. In one embodiment, the command to trigger refresh comprises an auto refresh command. In one embodiment, the command to trigger refresh comprises a self-refresh command. 1

In one aspect, a system includes: a memory controller to issue a refresh command; and multiple memory devices coupled to the memory controller, the memory devices including command interface logic to receive a command to trigger refresh of the memory device, wherein the memory device is one of multiple memory devices to be refreshed in response to the refresh command from the memory controller; and refresh logic to refresh the memory device in response to receipt of the command, including to initiate the refresh with a timing offset relative to another of the multiple memory devices.

In one embodiment, the memory device comprises a memory die. In one embodiment, the memory die comprises one of multiple dies in a stack of memory dies. In one embodiment, the multiple memory device comprise dynamic random access memory (DRAM) devices compliant with a high bandwidth memory (HBM) standard. In one embodiment, the multiple memory devices further comprising: a mode register to store a configuration setting to indicate a delay for initiation of the refresh. In one embodiment, the command interface logic is to receive the refresh command from the memory controller and delay initiation of the refresh in accordance with the configuration setting. In one embodiment, the multiple memory devices include different configuration settings to indicate different delays. In one embodiment, the command interface logic is to receive an indication from the at least one other memory device, wherein the at least one other memory device is to provide the indication after initiation of refresh of the at least one other memory device, to initiate refresh of the memory devices in sequence. In one embodiment, after initiation comprises after completion of the refresh. In one embodiment, the refresh of the memory device includes refresh of a determined number of multiple rows in response to the trigger. In one embodiment, refresh of the multiple rows comprises initiation of refresh of the multiple rows in sequence, with initiation timing offset relative to each other. In one embodiment, further comprising one or more of: at least one processor communicatively coupled to the memory controller; a display communicatively coupled to at least one processor; a battery to power the system; or a network interface communicatively coupled to at least one processor.

In one aspect, a method for refreshing a memory device includes: receiving a command to trigger refresh of the memory device, wherein the memory device is one of multiple memory devices to be refreshed in response to a refresh command from a memory controller; and in response to receipt of the command, initiating refresh of the memory device with a timing offset relative to at least one other of the multiple memory devices.

In one embodiment, the memory device comprises a memory die. In one embodiment, the memory die comprises one of multiple dies in a stack of memory dies. In one embodiment, the multiple memory device comprise dynamic random access memory (DRAM) devices compliant with a high bandwidth memory (HBM) standard. In one embodiment, initiating the refresh comprises: determining from a configuration setting of a mode register a delay for initiation of the refresh at the memory device; and delaying initiation of the refresh in accordance with the configuration setting. In one embodiment, the multiple memory devices include different configuration settings to indicate different delays. In one embodiment, receiving the command comprises: receiving an indication from the at least one other memory device, wherein the at least one other memory device is to provide the indication after initiation of refresh of the at least one other memory device, to initiate refresh of the memory devices in sequence. In one embodiment, providing the indication after initiation comprises providing the indication after completion of the refresh. In one embodiment, initiating the refresh of the memory device includes initiating refresh of a determined number of multiple rows in response to the trigger. In one embodiment, initiating refresh of the multiple rows comprises initiating refresh of the multiple rows in sequence, with initiation timing offset relative to each other. In one embodiment, receiving the command to trigger refresh comprises receiving an auto refresh command. In one embodiment, receiving the command to trigger refresh comprises receiving a self-refresh command.

In one aspect, an apparatus comprising means for performing operations to execute a method for refreshing a memory device in accordance with any embodiment of the preceding method. In one aspect, an article of manufacture comprising a computer readable storage medium having content stored thereon which when accessed causes a machine to perform operations to execute a method for refreshing a memory device in accordance with any embodiment of the preceding method.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware, software, or a combination. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, data, or a combination. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters or sending signals, or both, to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

1. A memory device, comprising:
command interface hardware to interface to one or more command signals lines and receive a command to trigger refresh of the memory device, wherein the memory device is one of multiple memory devices to be refreshed in response to a refresh command from a memory controller; and
refresh logic to refresh the memory device in response to receipt of the command, including to initiate refresh with a timing offset relative to at least one other memory device of the multiple memory devices;
wherein the command interface logic is to receive an indication from the at least one other memory device, wherein the at least one other memory device is to provide the indication after initiation of refresh of the at least one other memory device to cascade initiation of refresh of the multiple memory devices in sequence.

2. The memory device of claim 1, wherein the memory device comprises a memory die.

3. The memory device of claim 2, wherein the memory die comprises one of multiple dies in a stack of memory dies.

4. The memory device of claim 1, wherein the multiple memory device comprise dynamic random access memory (DRAM) devices compliant with a high bandwidth memory (HBM) standard.

5-8. (canceled)

9. The memory device of claim 1 wherein after initiation comprises after completion of the refresh.

10. The memory device of claim 1, wherein the refresh of the memory device includes refresh of a determined number of multiple rows in response to the trigger.

11. The memory device of claim 10, wherein refresh of the multiple rows comprises initiation of refresh of the multiple rows in sequence, with initiation timing offset relative to each other.

12. The memory device of claim 1, wherein the command to trigger refresh comprises an auto refresh command.

13. The memory device of claim 1, wherein the command to trigger refresh comprises a self-refresh command.

14. A system, comprising:
a memory controller to issue a refresh command; and
multiple memory devices coupled to the memory controller to receive the refresh command, wherein a memory device of the multiple memory devices including
command interface hardware to couple to the memory controller and receive a command to trigger refresh of the memory device; and
refresh logic to refresh the memory device in response to receipt of the command, including to initiate the refresh with a timing offset relative to at least one other memory device of the multiple memory devicesᵢ
wherein the command interface logic is to receive an indication from the at least one other memory device, wherein the at least one other memory device is to provide the indication after initiation of refresh of the at least one other memory device to cascade initiation of refresh of the multiple memory devices in sequence.

15. The system of claim 14, wherein the memory device comprises a memory die.

16. The system of claim 15, wherein the memory die comprises one of multiple dies in a stack of memory dies.

17. The system of claim 14, wherein the multiple memory device comprise dynamic random access memory (DRAM) devices compliant with a high bandwidth memory (HBM) standard.

18-21. (canceled)

22. The system of claim 14, wherein after initiation comprises after completion of the refresh.

23. The system of claim 14, wherein the refresh of the memory device includes refresh of a determined number of multiple rows in response to the trigger.

24. The system of claim 23, wherein refresh of the multiple rows comprises initiation of refresh of the multiple rows in sequence, with initiation timing offset relative to each other.

25. The system of claim 14, further comprising one or more of:
at least one processor communicatively coupled to the memory controller;
a display communicatively coupled to at least one processor;
a battery to power the system; or
a network interface communicatively coupled to at least one processor.

26. A method for refreshing a memory device, comprising:
receiving a command to trigger refresh of the memory device, wherein the memory device is one of multiple memory devices to be refreshed in response to a refresh command from a memory controller; and
in response to receipt of the command, initiating refresh of the memory device with a timing offset relative to at least one other memory device of the multiple memory devices;
wherein receiving the command includes receiving an indication from the at least one other memory device, wherein the at least one other memory device is to provide the indication after initiation of refresh of the at least one other memory device to cascade initiation of refresh of the multiple memory devices in sequence.

27-28. (canceled)
